(19) United States
(12) Patent Application Publication
(10) Pub. No.: US 2026/0076133 A1
(43) Pub. Date: Mar. 12, 2026

(54) SUBSTRATE PROCESSING APPARATUS AND SUBSTRATE PROCESSING METHOD

(71) Applicant: SCREEN Holdings Co., Ltd., Kyoto (JP)

(72) Inventor: Takashi IZUTA, Kyoto (JP)

(21) Appl. No.: 19/322,639

(22) Filed: Sep. 8, 2025

(30) Foreign Application Priority Data
Sep. 11, 2024 (JP) 2024-157723
Aug. 8, 2025 (JP) 2025-133761

(51) Int. Cl. H01L 21/67; B01D 29/56; B01D 29/60; B01D 29/66; B01D 35/157; C11D 7/08; G03F 7/42

(52) U.S. Cl. CPC H10P 72/0416; B01D 29/56; B01D 29/60; B01D 29/66; B01D 35/1573; C11D 7/08; B01D 2201/165; G03F 7/422

(57) ABSTRACT

Provided is a substrate processing apparatus that makes it possible to prevent or reduce a problem caused by mixing of a processing liquid for processing a substrate and a processing liquid for cleaning a filter. A substrate processing apparatus (100) includes: a circulation pipe (21) that includes a part branching into two pipes, which are a first branch pipe and a second branch pipe; a filter (53) that filters a first processing liquid and that is provided to at least the first branch pipe; and a controller (73) that carries out a first cleaning process in which a second processing liquid is allowed to flow into the first branch pipe in a backward direction, and then a third processing liquid is allowed to flow into the first branch pipe in the backward direction.

This Nonprovisional application claims priority under 35 U.S.C. § 119 on Patent Application No. 2024-157723 filed in Japan on Sep. 11, 2024, and, Patent Application No. 2025-133761 filed in Japan on Aug. 8, 2025, the entire contents of which are hereby incorporated by reference.

### TECHNICAL FIELD

The present invention relates to a substrate processing apparatus and a substrate processing method.

### BACKGROUND ART

Patent Literature 1 discloses an example of a substrate processing apparatus that uses a stripping liquid to carry out a stripping process with respect to a film adhered to a substrate. Upon completion of the stripping process, by causing a cleaning liquid to flow backward to a circulation filter, the substrate processing apparatus carries out a filter cleaning process for cleaning the circulation filter. This makes it possible to remove photoresist film fragments having adhered to the circulation filter, so that maintenance of the circulation filter can be easily carried out.

### CITATION LIST

### Patent Literature

### Patent Literature 1

Japanese Patent Application Publication Tokukai No. 2014-107478

### SUMMARY OF INVENTION

### Technical Problem

However, in a case where the stripping process is resumed after the filter cleaning process in a state in which the circulation filter and its vicinity are filled with the cleaning liquid, the substrate processing apparatus of Patent Literature 1 is in a state in which the stripping liquid and the cleaning liquid are mixed. In this case, a problem may occur depending on, for example, a type or state of each of the stripping liquid and the cleaning liquid.

An object of an aspect of the present invention is to provide, for example, a substrate processing apparatus that makes it possible to prevent or reduce a problem caused by mixing of a processing liquid for processing a substrate and a processing liquid for cleaning a filter.

### Solution to Problem

In order to attain the object, a substrate processing apparatus in accordance with an aspect of the present invention includes: a substrate process tank that uses a liquid containing a first processing liquid to process a substrate; a circulation pipe that has both ends connected to the substrate process tank and that includes a part branching into two pipes, which are a first branch pipe and a second branch pipe; a filter that filters the first processing liquid; a second processing liquid supply section that supplies a second processing liquid containing a component different from a component of the first processing liquid; a third processing liquid supply section that supplies a third processing liquid containing a component different from the component of the second processing liquid; a discharge section that discharges a liquid containing at least the first processing liquid or the second processing liquid; a controller; a first switching section that switches whether to allow the first processing liquid to flow into the first branch pipe or the second branch pipe; and a second switching section that switches whether to allow the second processing liquid to flow into the first branch pipe or the second branch pipe and whether to allow the third processing liquid to flow into the first branch pipe or the second branch pipe, the filter is provided to at least the first branch pipe, and the controller (1) carries out a first cleaning process in which, during a period in which the first switching section is controlled so as to allow the first processing liquid to flow into the second branch pipe in a forward direction, the second switching section is controlled so as to (i) allow the second processing liquid to flow into the first branch pipe in a backward direction and (ii) discharge, from the discharge section, the liquid containing at least the first processing liquid, and then the second switching section is further controlled so as to (iii) allow the third processing liquid to flow into the first branch pipe in the backward direction and (iv) discharge, from the discharge section, the liquid containing at least the second processing liquid, and (2) after the first cleaning process, allows the first processing liquid to flow into the first branch pipe in the forward direction, and allowing the second processing liquid and the third processing liquid to flow into the second branch pipe in the backward direction, or stops supply of the second processing liquid and the third processing liquid.

The substrate processing apparatus in accordance with an aspect of the present invention may be configured such that the circulation pipe has first and second branch points at which the circulation pipe branches into the first branch pipe and the second branch pipe, the first switching section includes a pair of first circulation valves provided to the first branch pipe, and a pair of second circulation valves provided to the second branch pipe, the filter is provided between the pair of first circulation valves, and the controller allows the first processing liquid to flow into the first branch pipe by opening the pair of first circulation valves and closing the pair of second circulation valves, and allows the first processing liquid to flow into the second branch pipe by closing the pair of first circulation valves and opening the pair of second circulation valves.

The substrate processing apparatus in accordance with an aspect of the present invention may be configured to further include a first supply pipe which connects the second processing liquid supply section and the third processing liquid supply section with the first branch pipe, a second supply pipe which connects the second processing liquid supply section and the third processing liquid supply section with the second branch pipe, and a discharge pipe which connects the first branch pipe and the second branch pipe with the discharge section, the first branch pipe having a third branch point which is between the filter and one of the pair of first circulation valves on a downstream side in the forward direction and at which the first supply pipe branches off from the first branch pipe, the second branch pipe having a fourth branch point which is between the filter and one of the pair of second circulation valves on the downstream side in the forward direction and at which the second supply pipe branches off from the second branch pipe, the first branch pipe having a fifth branch point which is between the filter and the other of the pair of first circulation valves on an upstream side in the forward direction and at which the discharge pipe branches off from the first branch pipe, the second branch pipe having a sixth branch point which is between the filter and the other of the pair of second circulation valves on the upstream side in the forward direction and at which the discharge pipe branches off from the second branch pipe, the second switching section including a first supply valve which is located on the first supply pipe side of the third branch point, a second supply valve which is located on the second supply pipe side of the fourth branch point, a first discharge valve which is located on the discharge pipe side of the fifth branch point, and a second discharge valve which is located on the discharge pipe side of the sixth branch point, while allowing the first processing liquid to flow into the first branch pipe by opening the pair of first circulation valves and closing the pair of second circulation valves, the controller closing the first supply valve, opening the second supply valve, closing the first discharge valve, and opening the second discharge valve, and while allowing the first processing liquid to flow into the second branch pipe by closing the pair of first circulation valves and opening the pair of second circulation valves, the controller opening the first supply valve, closing the second supply valve, opening the first discharge valve, and closing the second discharge valve.

The substrate processing apparatus in accordance with an aspect of the present invention may be configured such that the filter is further provided to the second branch pipe, and the controller (1) carries out a second cleaning process in which, during a period in which the first switching section is controlled so as to allow the first processing liquid to flow into the first branch pipe in the forward direction, the second switching section is controlled so as to (i) allow the second processing liquid to flow into the second branch pipe in the backward direction and (ii) discharge, from the discharge section, the liquid containing at least the first processing liquid, and then the second switching section is further controlled so as to (iii) allow the third processing liquid to flow into the second branch pipe in the backward direction and (iv) discharge, from the discharge section, the liquid containing at least the second processing liquid, and (2) after the second cleaning process, allows the first processing liquid to flow into the second branch pipe in the forward direction, and allows the second processing liquid and the third processing liquid to flow into the first branch pipe in the backward direction, or stops supply of the second processing liquid and the third processing liquid.

The substrate processing apparatus in accordance with an aspect of the present invention may be configured such that the first processing liquid is a processing liquid containing sulfuric acid, and the second processing liquid is pure water.

The substrate processing apparatus in accordance with an aspect of the present invention may be configured such that the first processing liquid is phosphoric acid, and the second processing liquid is a processing liquid containing hydrofluoric acid.

The substrate processing apparatus in accordance with an aspect of the present invention may be configured such that the circulation pipe includes a heater which heats the first processing liquid to a prescribed temperature, and the second processing liquid supply section supplies the second processing liquid at normal temperature.

The substrate processing apparatus in accordance with an aspect of the present invention may be configured such that the third processing liquid supply section supplies the third processing liquid to the filter by branching off from the circulation pipe, and the third processing liquid is the first processing liquid which circulates in the circulation pipe.

The substrate processing apparatus in accordance with an aspect of the present invention may be configured such that the substrate process tank includes an inner tank which stores the first processing liquid that has been supplied from the circulation pipe and an outer tank which stores the first processing liquid that has overflowed from the inner tank, the circulation pipe has one end which is connected to the outer tank and the other end which is connected to the inner tank, and the third processing liquid supply section supplies the third processing liquid to the filter at a flow rate lower than a flow rate at which the first processing liquid overflows from the inner tank to the outer tank.

The substrate processing apparatus in accordance with an aspect of the present invention may be configured such that in the second cleaning process, the controller allows the third processing liquid to flow into the second branch pipe in the backward direction immediately before an end of a period in which the first switching section is controlled so as to circulate the first processing liquid in the first branch pipe, and in the first cleaning process, the controller allows the third processing liquid to flow into the first branch pipe in the backward direction immediately before an end of a period in which the first switching section is controlled so as to circulate the first processing liquid in the second branch pipe.

The substrate processing apparatus in accordance with an aspect of the present invention may be configured such that the second switching section further includes a first-second supply valve which switches whether the second processing liquid flows from the second processing liquid supply section into the first branch pipe, a first-third supply valve which switches whether the third processing liquid flows from the third processing liquid supply section into the first branch pipe, a second-second supply valve which switches whether the second processing liquid flows from the second processing liquid supply section into the second branch pipe, and a second-third supply valve which switches whether the third processing liquid flows from the third processing liquid supply section into the second branch pipe, and the controller carries out control such that, in a state in which the pair of first circulation valves is opened, the pair of second circulation valves is closed, and the second supply valve is opened, the second-second supply valve is opened for a prescribed period, and then the second-third supply valve is opened for a prescribed period, and such that, in a state in which the pair of second circulation valves is opened, the pair of first circulation valves is closed, and the first supply valve is opened, the first-second supply valve is opened for a prescribed period, and then the first-third supply valve is opened for a prescribed period.

The substrate processing apparatus in accordance with an aspect of the present invention may be configured to further include a main filter which is provided on the downstream side of the filter in the circulation pipe, the filter being a prefilter, and the main filter having a smaller pore diameter than the prefilter.

The substrate processing apparatus in accordance with an aspect of the present invention may be configured such that a member which is included in the substrate process tank and through which the first processing liquid passes is made of a material containing quartz.

A substrate processing method in accordance with an aspect of the present invention is a substrate processing method carried out in a substrate processing apparatus including: a substrate process tank that uses a liquid containing a first processing liquid to process a substrate; a circulation pipe that has both ends connected to the substrate process tank and that includes a part branching into two pipes, which are a first branch pipe and a second branch pipe; a filter that filters the first processing liquid; a second processing liquid supply section that supplies a second processing liquid containing a component different from a component of the first processing liquid; a third processing liquid supply section that supplies a third processing liquid containing a component different from the component of the second processing liquid; a discharge section that discharges a liquid containing at least the first processing liquid or the second processing liquid; a first switching section that switches whether to allow the first processing liquid to flow into the first branch pipe or the second branch pipe; and a second switching section that switches whether to allow the second processing liquid to flow into the first branch pipe or the second branch pipe and whether to allow the third processing liquid to flow into the first branch pipe or the second branch pipe, wherein the filter is provided to at least the first branch pipe, (1) a first cleaning process is carried out in which, during a period in which the first switching section is controlled so as to allow the first processing liquid to flow into the second branch pipe in a forward direction, the second switching section is controlled so as to (i) allow the second processing liquid to flow into the first branch pipe in a backward direction and (ii) discharge, from the discharge section, the liquid containing at least the first processing liquid, and then the second switching section is further controlled so as to (iii) allow the third processing liquid to flow into the first branch pipe in the backward direction and (iv) discharge, from the discharge section, the liquid containing at least the second processing liquid, and (2) after the first cleaning process, the first processing liquid is allowed to flow into the first branch pipe in the forward direction, and the second processing liquid and the third processing liquid are allowed to flow into the second branch pipe in the backward direction, or supply of the second processing liquid and the third processing liquid is stopped.

A substrate processing method in accordance with an aspect of the present invention includes: a substrate processing step of using a liquid containing a first processing liquid to process a substrate in a substrate process tank; a circulation processing step of using a filter provided to at least a first branch pipe of a circulation pipe to filter the first processing liquid which flows in the circulation pipe in a forward direction, the circulation pipe having both ends connected to the substrate process tank, and including a part branching into two pipes, which are the first branch pipe and a second branch pipe; and a processing resumption step of (I) carrying out a first cleaning process in which, during a period in which a first switching section that switches whether to allow the first processing liquid to flow into the first branch pipe or the second branch pipe is controlled so as to allow the first processing liquid to flow into the second branch pipe in a forward direction, a second switching section that switches whether to allow a second processing liquid containing a component different from a component of the first processing liquid to flow into the first branch pipe or the second branch pipe and whether to allow a third processing liquid containing a component different from the component of the second processing liquid to flow into the first branch pipe or the second branch pipe is controlled so as to (i) allow the second processing liquid to flow into the first branch pipe in a backward direction and (ii) discharge, from a discharge section that discharges a liquid containing at least the first processing liquid or the second processing liquid, the liquid containing at least the first processing liquid, and then the second switching section is further controlled so as to (iii) allow the third processing liquid to flow into the first branch pipe in the backward direction and (iv) discharge, from the discharge section, the liquid containing at least the second processing liquid, and (II) after the first cleaning process, resuming circulation of the first processing liquid in the first branch pipe.

### Advantageous Effects of Invention

For example, a substrate processing apparatus in accordance with an aspect of the present invention makes it possible to prevent or reduce a problem caused by mixing of a processing liquid for processing a substrate and a processing liquid for cleaning a filter.

### BRIEF DESCRIPTION OF DRAWINGS

FIG. 1 is an overall view schematically illustrating a configuration of a substrate processing apparatus in accordance with Embodiment 1.

FIG. 2 is a cross-sectional view illustrating a shape of an upflow pipe.

FIG. 3 is a flowchart illustrating an operation of the substrate processing apparatus in accordance with Embodiment 1.

FIG. 4 is a timing chart representing open/closed states of valves and control valves of a switching section in the substrate processing apparatus in accordance with Embodiment 1.

FIG. 5 is a diagram illustrating the open/closed states of the valves of the switching section in the substrate processing apparatus in accordance with Embodiment 1.

FIG. 6 is a diagram illustrating the open/closed states of the valves of the switching section in the substrate processing apparatus in accordance with Embodiment 1.

FIG. 7 is a diagram illustrating the open/closed states of the valves of the switching section in the substrate processing apparatus in accordance with Embodiment 1.

FIG. 8 is a diagram illustrating the open/closed states of the valves of the switching section in the substrate processing apparatus in accordance with Embodiment 1.

FIG. 9 is a diagram illustrating the open/closed states of the valves of the switching section in the substrate processing apparatus in accordance with Embodiment 1.

FIG. 10 is an overall view schematically illustrating a configuration of a substrate processing apparatus in accordance with Embodiment 2.

FIG. 11 is a flowchart illustrating an operation of the substrate processing apparatus in accordance with Embodiment 2.

FIG. 12 is a diagram illustrating open/closed states of valves of a switching section in the substrate processing apparatus in accordance with Embodiment 2.

FIG. 13 is a diagram illustrating the open/closed states of the valves of the switching section in the substrate processing apparatus in accordance with Embodiment 2.

FIG. 14 is a diagram illustrating the open/closed states of the valves of the switching section in the substrate processing apparatus in accordance with Embodiment 2.

FIG. 15 is a diagram illustrating the open/closed states of the valves of the switching section in the substrate processing apparatus in accordance with Embodiment 2.

FIG. 16 is an overall view schematically illustrating a configuration of a substrate processing apparatus in accordance with Embodiment 3.

FIG. 17 is an overall view schematically illustrating a configuration of a substrate processing apparatus in accordance with Embodiment 4.

FIG. 18 is an overall view schematically illustrating a configuration of a substrate processing apparatus in accordance with Embodiment 5.

### DESCRIPTION OF EMBODIMENTS

### Embodiment 1

An embodiment of the present invention will be described below with reference to the drawings. In the following description, “A to B”, which indicates a numerical range, means “not less than A and not more than B”, unless otherwise noted.

### (Configuration)

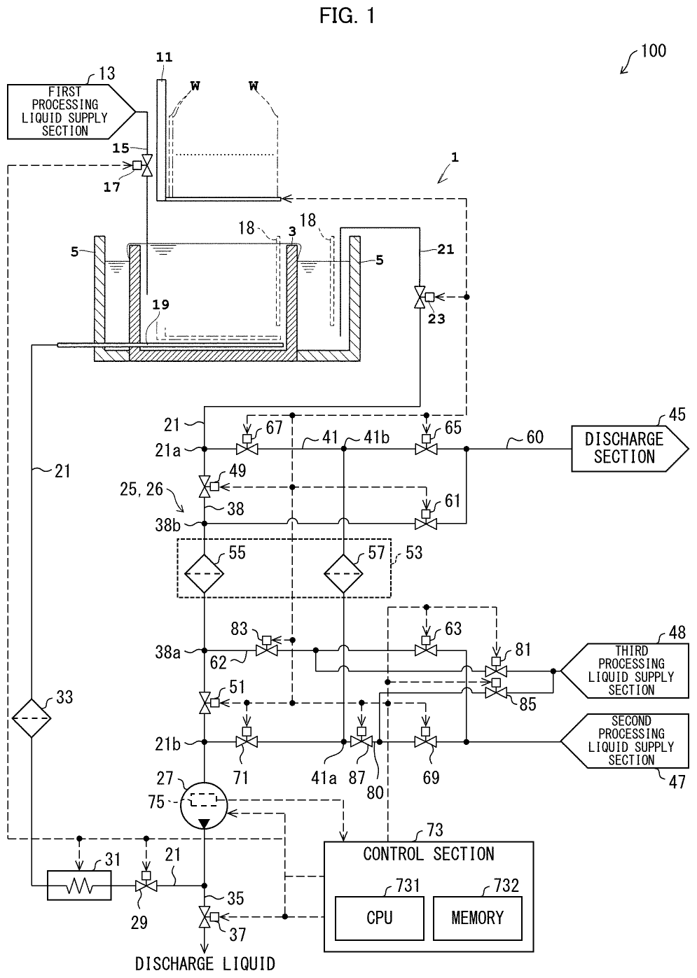

FIG. 1 is an overall view schematically illustrating a configuration of a substrate processing apparatus 100 in accordance with Embodiment 1. The substrate processing apparatus 100 is a processing apparatus that processes a substrate W. The substrate W is, for example, a semiconductor wafer. The substrate processing apparatus 100 of FIG. 1 is a so-called batch-type processing apparatus that can collectively process a lot of a plurality of substrates W.

The substrate processing apparatus 100 includes a substrate process tank (substrate processing section) 1, a circulation pipe 21, a filter 53, a second processing liquid supply section 47, a third processing liquid supply section 48, a discharge section 45, and a controller (control section) 73 as illustrated in FIG. 1.

The substrate process tank 1 uses a first processing liquid to process a substrate W. The first processing liquid is a cleaning liquid for cleaning a surface of the substrate W. For example, the first processing liquid is a processing liquid containing sulfuric acid or is phosphoric acid. In a case where the first processing liquid is a processing liquid containing sulfuric acid, the first processing liquid may be a mixed solution of sulfuric acid and a hydrogen peroxide solution (sulfuric acid-hydrogen peroxide mixture (SPM)). In this case, the substrate process tank 1 carries out so-called SPM cleaning. By this SPM cleaning, the substrate process tank 1 removes an organic substance that has adhered to the surface of the substrate W, such as a photoresist. In a case where the first processing liquid is phosphoric acid, the substrate process tank 1 removes a nitride film that has been formed on the surface of the substrate W.

The substrate process tank 1 includes an inner tank 3 and an outer tank 5. The inner tank 3 is a tank which stores the first processing liquid and in which the substrate W is processed. The outer tank 5 is a tank which stores a first processing liquid that has overflowed from the inner tank 3. The inner tank 3 and the outer tank 5 each may be provided with a liquid level sensor 18 that detects a liquid level of the first processing liquid. The liquid level indicates a height of a surface of the first processing liquid that is stored in the inner tank 3 or the outer tank 5. Further, the inner tank 3 is provided with a temperature sensor (not illustrated) that detects a temperature of the first processing liquid.

The substrate processing apparatus 100 further includes a lifter 11. The lifter 11 is disposed at or near the substrate process tank 1. The lifter 11 is configured to be capable of being raised and lowered between a “waiting position” corresponding to a space above the substrate process tank 1 and a “processing position” corresponding to an inner part of the inner tank 3. The lifter 11 holds a plurality of substrates W in an upright posture in a state in which the plurality of substrates W are maintained at prescribed intervals.

The substrate processing apparatus 100 further includes a first processing liquid supply section 13. The first processing liquid supply section 13 supplies the first processing liquid to the inner tank 3. The first processing liquid supply section 13 is provided at or near the substrate process tank 1. The substrate processing apparatus 100 further includes: a first processing liquid supply pipe 15 one end of which is connected to the first processing liquid supply section 13 and the other end of which is connected to the inner tank 3; and a control valve 17 which is for switching between a state in which the first processing liquid can flow in the first processing liquid supply pipe 15 and a state in which the first processing liquid cannot flow in the first processing liquid supply pipe 15.

The circulation pipe 21 is a pipe that has both ends connected to the substrate process tank 1. The first processing liquid circulates in the circulation pipe 21 in a forward direction. Specifically, one end of the circulation pipe 21 is connected to the outer tank 5. The other end of the circulation pipe 21 is connected to the inner tank 3. The forward direction is a direction in which the first processing liquid travels from the outer tank 5 to the inner tank 3 in the circulation pipe 21. That is, the first processing liquid is circulated from the outer tank 5 via the circulation pipe 21 and supplied to the inner tank 3 from the circulation pipe 21. In other words, the inner tank 3 is a tank that stores the first processing liquid which has been supplied from the circulation pipe 21. The outer tank 5 is a tank that stores the first processing liquid which has overflowed from the inner tank 3. In the following description, the terms “upstream side” and “downstream side” mean an upstream side and a downstream side, respectively, in the forward direction.

The circulation pipe 21 is provided with a control valve 23, a filter 53, a bellows pump 27, a control valve 29, a heater 31, and a main filter 33 in order from the upstream side. The control valve 23 switches between a state in which the processing liquid can flow in the circulation pipe 21 and a state in which the processing liquid cannot flow in the circulation pipe 21. The filter 53 and the main filter 33 filter the first processing liquid. This allows a foreign matter in the first processing liquid to be collected by the filter 53 and the main filter 33. Details of the filter 53 and the main filter 33 will be described later. The bellows pump 27 feeds the processing liquid under pressure from the outer tank 5 to the inner tank 3 in the forward direction via the circulation pipe 21. The control valve 29 switches between a state in which the processing liquid can circulate in the circulation pipe 21 and a state in which the processing liquid cannot circulate in the circulation pipe 21. The heater 31 heats the first processing liquid to a prescribed temperature. The bellows pump 27 includes a stroke sensor 75, and output of the stroke sensor 75 is given to the controller 73. The stroke sensor 75 detects an end position in a back-and-forth movement of a bellows (not illustrated) in the bellows pump 27.

A liquid discharge pipe 35 is communicably connected to a side that is downstream of the bellows pump 27 and that is upstream of the control valve 29. The liquid discharge pipe 35 is provided with a control valve 37 that switches between a state in which the processing liquid flowing in the circulation pipe 21 is discharged from the liquid discharge pipe 35 and a state in which the processing liquid flowing in the circulation pipe 21 is not discharged from the liquid discharge pipe 35. The control valve 37 is opened as needed to discharge the first processing liquid from the liquid discharge pipe 35.

The substrate process tank 1 further includes an upflow pipe 19 through which the first processing liquid passes. The upflow pipe 19 is a pipe that is for supplying, into the inner tank 3, the first processing liquid which has circulated in the circulation pipe 21. A part of the upflow pipe 19 is disposed at or near a bottom of the inner tank 3. The other part of the upflow pipe 19 penetrates wall surfaces of the inner tank 3 and the outer tank 5 and is exposed outside the substrate process tank 1.

A downstream side end part of the circulation pipe 21 is connected to a part of the upflow pipe 19 which part is exposed outside the substrate process tank 1. In other words, the circulation pipe 21 is connected to the inner tank 3 via the upflow pipe 19. The upflow pipe 19 may be made of a material containing, for example, quartz.

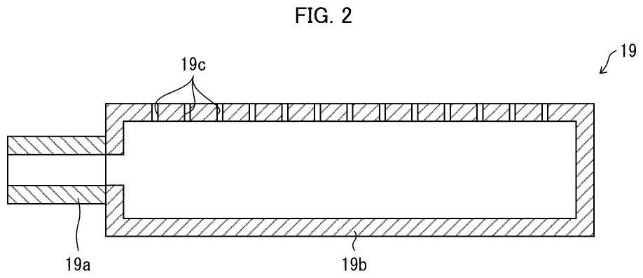

FIG. 2 is a cross-sectional view illustrating a shape of the upflow pipe 19. In consideration of visibility, in FIG. 2, an aspect ratio of the upflow pipe 19 is different from aspect ratios of a real upflow pipe and the upflow pipe illustrated in FIG. 1. The upflow pipe 19 has a base end part 19a and an ejection pipe part 19b as illustrated in FIG. 2.

The upflow pipe 19 has a plurality of ejection holes 19c through which the first processing liquid is ejected. For simplicity, in FIG. 2, only some of the plurality of ejection holes 19c are given reference signs. The ejection holes 19c are provided to the ejection pipe part 19b and are not provided to the base end part 19a. The entire ejection pipe part 19b and a part of the base end part 19a are located in the inner tank 3. The other part of the base end part 19a penetrates the wall surfaces of the inner tank 3 and the outer tank 5 and is exposed outside the substrate process tank 1. The downstream side end part of the circulation pipe 21 is connected to the base end part 19a. The first processing liquid flows through the circulation pipe 21 to flow into the base end part 19a, and flows into the inner tank 3 through the ejection holes 19c that are provided to the ejection pipe part 19b.

The circulation pipe 21 includes a part branching into two pipes, which are a first branch pipe 38 and a second branch pipe 41. The circulation pipe 21 has first and second branch points 21a and 21b at which the circulation pipe 21 branches into the first branch pipe 38 and the second branch pipe 41.

In Embodiment 1, the filter 53 includes a first filter 55 that is provided to the first branch pipe 38 and a second filter 57 that is provided to the second branch pipe 41. In the following description, in a case where it is not necessary to distinguish between the first filter 55 and the second filter 57, these filters are each sometimes collectively referred to as a “filter 53”.

The main filter 33 is provided on the downstream side of the filter 53 in the circulation pipe 21. That is, the filter 53 functions as a prefilter that filters the first processing liquid which has not been filtered by the main filter 33. In this case, the main filter 33 has a smaller pore diameter than the filter 53. The pore diameter is an average of diameters of pores that are provided in a filter.

The filter 53 has a pore diameter of, for example, 0.1 mm. The main filter 33 has a pore diameter of, for example, 30 nm to 50 nm.

According to the above configuration, the filter 53 that functions as a prefilter collects a relatively large foreign matter earlier than the main filter 33. This makes it possible to prevent clogging of the main filter 33 due to a relatively large foreign matter.

The circulation pipe 21 further includes a first switching section 25 and a second switching section 26. The first switching section 25 switches whether to allow a first processing liquid to flow into the first branch pipe 38 or the second branch pipe 41. The second switching section 26 switches whether to allow a second processing liquid to flow into the first branch pipe 38 or the second branch pipe 41 and whether to allow a third processing liquid to flow into the first branch pipe 38 or the second branch pipe 41. Specific configurations of the first switching section 25 and the second switching section 26 will be described later.

The second processing liquid supply section 47 supplies the second processing liquid containing a component different from a component of the first processing liquid. The third processing liquid supply section 48 supplies the third processing liquid containing a component different from the component of the second processing liquid. The substrate processing apparatus 100 includes a first supply pipe 62 which connects the second processing liquid supply section 47 and the third processing liquid supply section 48 with the first branch pipe 38 and a second supply pipe 80 which connects the second processing liquid supply section 47 and the third processing liquid supply section 48 with the second branch pipe 41.

In a case where the first processing liquid is a processing liquid containing sulfuric acid, the second processing liquid may be pure water. This makes it possible not only to use a processing liquid containing sulfuric acid to remove an organic substance that is adhered to the substrate W, but also to use pure water to appropriately clean the filter 53 that has collected the organic substance (foreign matter).

In a case where the first processing liquid is phosphoric acid, the second processing liquid may be a processing liquid containing hydrofluoric acid. This makes it possible not only to use phosphoric acid to remove the nitride film that has been formed on the substrate W, but also to use hydrofluoric acid to appropriately clean the filter 53 that has collected silicon (foreign matter) deposited by a phosphate treatment.

In a case where the first processing liquid is phosphoric acid and the second processing liquid is a processing liquid containing hydrofluoric acid, the second processing liquid supply section 47 may supply the second processing liquid to the filter 53 and then further supply pure water to the filter 53. Alternatively, the substrate processing apparatus 100 may further include, in addition to the second processing liquid supply section 47, a pure water supply source that supplies pure water to the filter 53.

The third processing liquid is a liquid that does not bump when mixed with the first processing liquid. In a case where the first processing liquid is a processing liquid containing sulfuric acid, the third processing liquid may be, for example, sulfuric acid. In a case where the first processing liquid is phosphoric acid, the third processing liquid may be, for example, phosphoric acid.

An example of the specific configuration of the first switching section 25 will be described below. In an example illustrated in FIG. 1, the first switching section 25 includes a pair of first circulation valves 49 and 51 provided to the first branch pipe 38 and a pair of second circulation valves 67 and 71 provided to the second branch pipe 41.

The first circulation valves 49 and 51 switch between a state in which the first processing liquid flows in the first branch pipe 38 and a state in which the first processing liquid does not flow in the first branch pipe 38. The first filter 55 is provided between the pair of first circulation valves 49 and 51. Specifically, the first circulation valve 49 and the first circulation valve 51 are located on the upstream side and the downstream side, respectively, of the first filter 55 in the forward direction.

The second circulation valves 67 and 71 switch between a state in which the first processing liquid flows in the second branch pipe 41 and a state in which the first processing liquid does not flow in the second branch pipe 41. The second filter 57 is provided between the pair of second circulation valves 67 and 71. Specifically, the second circulation valve 67 and the second circulation valve 71 are located on the upstream side and the downstream side, respectively, of the second filter 57 in the forward direction.

The first branch pipe 38 has a third branch point 38a which is between the filter 53 and the first circulation valve 51 on the downstream side in the forward direction and at which the first supply pipe 62 branches off from the first branch pipe 38. The second branch pipe 41 has a fourth branch point 41a which is between the filter 53 and the second circulation valve 71 on the downstream side in the forward direction and at which the second supply pipe 80 branches off from the second branch pipe 41.

The discharge section 45 discharges, from the upstream side of the filter 53, a liquid containing at least the first processing liquid or the second processing liquid. The substrate processing apparatus 100 further includes a discharge pipe 60 which connects the first branch pipe 38 and the second branch pipe 41 with the discharge section 45. The first branch pipe 38 has a fifth branch point 38b which is between the filter 53 and the first circulation valve 49 on the upstream side in the forward direction and at which the discharge pipe 60 branches off from the first branch pipe 38. The second branch pipe 41 has a sixth branch point 41b which is between the filter 53 and the second circulation valve 67 on the upstream side in the forward direction and at which the discharge pipe 60 branches off from the second branch pipe 41.

An example of the specific configuration of the second switching section 26 will be described below. In the example illustrated in FIG. 1, the second switching section 26 includes a first supply valve 83 which is located on the first supply pipe 62 side of the third branch point 38a, a second supply valve 87 which is located on the second supply pipe 80 side of the fourth branch point 41a, a first discharge valve 61 which is located on the discharge pipe 60 side of the fifth branch point 38b, and a second discharge valve 65 which is located on the discharge pipe 60 side of the sixth branch point 41b. The first supply valve 83 switches between a state in which the second processing liquid and the third processing liquid flow in the first supply pipe 62 and a state in which the second processing liquid and the third processing liquid do not flow in the first supply pipe 62. The second supply valve 87 switches between a state in which the second processing liquid and the third processing liquid flow in the second supply pipe 80 and a state in which the second processing liquid and the third processing liquid do not flow in the second supply pipe 80. The first discharge valve 61 switches between a state in which the second processing liquid and the third processing liquid flow from the first branch pipe 38 into the discharge section 45 and a state in which the second processing liquid and the third processing liquid do not flow from the first branch pipe 38 into the discharge section 45. The second discharge valve 65 switches between a state in which the second processing liquid and the third processing liquid flow from the second branch pipe 41 into the discharge section 45 and a state in which the second processing liquid and the third processing liquid do not flow from the second branch pipe 41 into the discharge section 45.

The second switching section 26 further includes a first-second supply valve 63, a first-third supply valve 81, a second-second supply valve 69, and a second-third supply valve 85. The first-second supply valve 63 switches whether the second processing liquid flows from the second processing liquid supply section 47 into the first branch pipe 38. The first-third supply valve 81 switches whether the third processing liquid flows from the third processing liquid supply section 48 into the first branch pipe 38. The second-second supply valve 69 switches whether the second processing liquid flows from the second processing liquid supply section 47 into the second branch pipe 41. The second-third supply valve 85 switches whether the third processing liquid flows from the third processing liquid supply section 48 into the second branch pipe 41.

The controller 73 controls each section of the substrate processing apparatus 100 and controls an operation of the substrate processing apparatus 100. The controller 73 includes at least one processor or circuit. The at least one processor or circuit may include, but is not limited to, a central processing unit (CPU), a micro processing unit (MPU), a graphics processing unit (GPU), an application-specific integrated circuit (ASIC), or a field-programmable gateway (FPGA). In FIG. 1, the controller 73 includes a CPU 731. The controller 73 further includes a memory 732, which is a storage medium. The storage medium can also be referred to as a non-transitory computer-readable medium. The storage medium may include, but is not limited to, a hard disk (HD) or a random access memory (RAM). In FIG. 1, a dashed arrow indicates a signal flow between each section of the substrate processing apparatus 100 and the controller 73. In the present embodiment, an operation that is carried out by the controller 73 controlling each component is sometimes described as being carried out by the each component. Details of an object to be controlled by the controller 73 will be described in the operation of the substrate processing apparatus 100 (described later).

### (Operation)

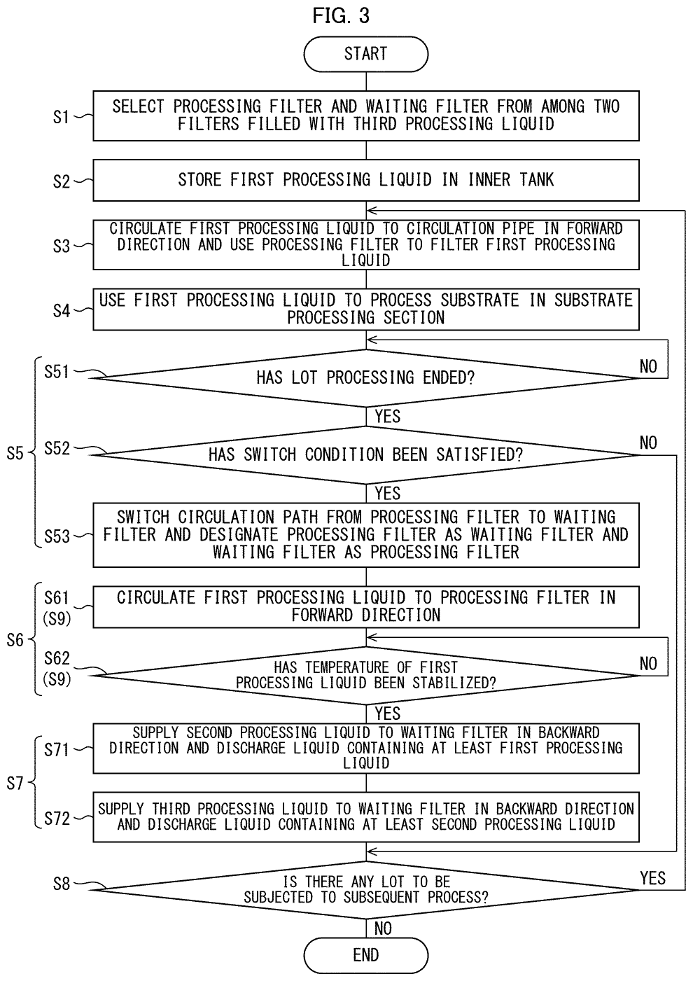

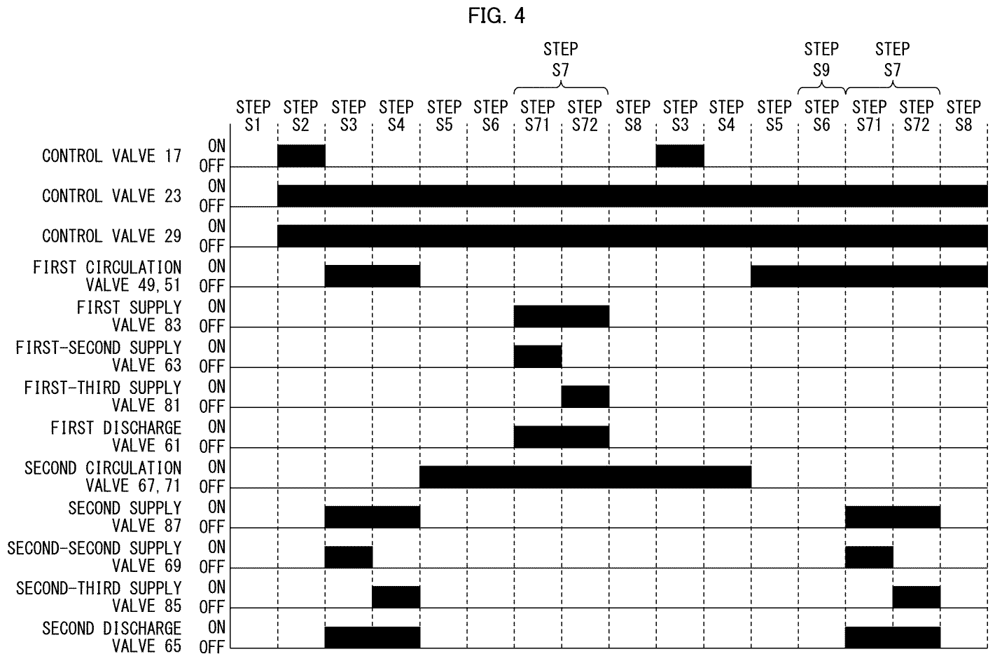

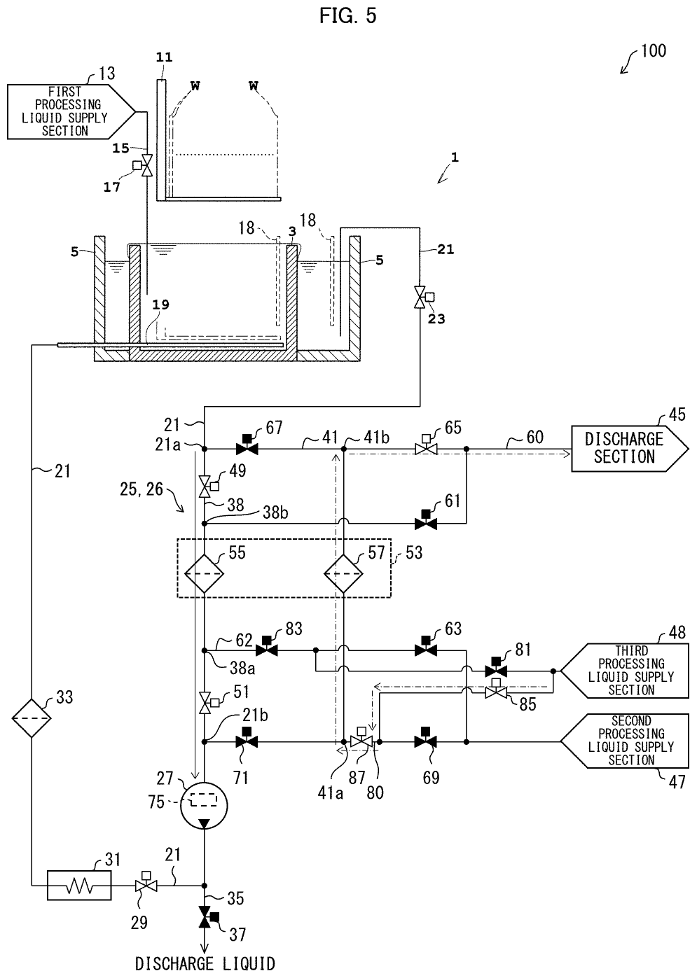

The operation of the substrate processing apparatus 100 will be described with reference to FIGS. 3 to 9. FIG. 3 is a flowchart illustrating the operation of the substrate processing apparatus 100. FIG. 4 is a timing chart representing open/closed states of the valves of the first switching section 25 and the second switching section 26, the control valve 17, the control valve 23, and the control valve 29. In FIG. 4, the open state and the closed state are described as “ON” and “OFF”, respectively. FIGS. 5 to 9 are diagrams illustrating the open/closed states of the valves of the first switching section 25 and the second switching section 26. In FIGS. 5 to 9, a valve that is among the valves of the first switching section 25 and the second switching section 26 and that is closed is illustrated in black. Further, in FIGS. 5 to 9, the controller 73 is omitted.

The controller 73 carries out a filter selection step (S1) illustrated in FIG. 3. In the filter selection step (S1), the controller 73 selects, from among the first filter 55 and the second filter 57 of the filter 53, the following: a processing filter that carries out a process for collecting a foreign matter by circulating the first processing liquid in the forward direction; and a waiting filter that waits with the first processing liquid not circulated in the forward direction. Filter selection information, which is information pertaining to the filter 53 selected as each of the processing filter and the waiting filter, is temporarily stored in the memory 732 of the controller 73 illustrated in FIG. 1. In this case, the controller 73 controls the first switching section 25 so as to switch a pipe through which the first processing liquid circulates to a pipe that is among the first branch pipe 38 and the second branch pipe 41 and that includes the filter 53 selected as the processing filter.

The following description takes, as an example, a case where the controller 73 selects the first filter 55 and the second filter 57 as the processing filter and the waiting filter, respectively, in the filter selection step (S1). In a case where the first filter 55 is the processing filter, the controller 73 temporarily stores, as the filter selection information, the first filter 55, which is the processing filter, in the memory 732 of the controller 73. Further, the controller 73 controls the first switching section 25 so as to open the first circulation valves 49 and 51 and close the second circulation valves 67 and 71.

In the substrate processing apparatus 100, in a stage before the filter selection step (S1), the first filter 55 and the second filter 57 are each filled with the first processing liquid or the third processing liquid. In the substrate processing apparatus 100, upon replacement of the filter 53, the controller 73 carries out an activation operation to activate the filter 53. In the activation operation, the controller 73 sequentially supplies, for example, the first processing liquid, the second processing liquid, and the third processing liquid to the filter 53 so as to remove a foreign matter from the filter 53. Finally, the controller 73 causes the filter 53 to be filled with the first processing liquid or the third processing liquid. More specifically, by the time when the substrate processing apparatus 100 starts carrying out processing with respect to the substrate W, the first filter 55 has been filled with the first processing liquid or the third processing liquid. Note that, in the filter selection step (S1) of FIG. 3, a case where the filter 53 is filled with the third processing liquid is described for simplification.

The controller 73 carries out a first processing liquid storage step (S2) after the filter selection step (S1). In the first processing liquid storage step (S2), the controller 73 controls the control valve 17 and supplies the first processing liquid from the first processing liquid supply section 13 to the inner tank 3 of the substrate process tank 1. In this case, the controller 73 uses signals from the liquid level sensor 18 and the temperature sensor to confirm that the first processing liquid which has a prescribed liquid level and a prescribed temperature has been stored in the inner tank 3. A part of the first processing liquid that has been supplied to the inner tank 3 is stored in the outer tank 5 by overflow.

After the first processing liquid storage step (S2), the controller 73 carries out a circulation processing step (S3) illustrated in FIG. 3. In the circulation processing step (S3), the controller 73 controls the first switching section 25, the second switching section 26, the bellows pump 27, the control valve 23, and the control valve 29. On the basis of information from the memory 732 which information has been temporarily stored in the filter selection step (S1), the controller 73 controls the first circulation valves 49 and 51 of the first switching section 25 in order to circulate the first processing liquid to the first filter 55, which is the processing filter. Specifically, as illustrated in FIGS. 4 and 5, the controller 73 allows the first processing liquid to flow into the first branch pipe 38 by opening the pair of first circulation valves 49 and 51 and closing the pair of second circulation valves 67 and 71. Further, the controller 73 opens the control valve 23 and the control valve 29.

Thereafter, until processing carried out by the substrate processing apparatus 100 ends, the controller 73 controls the bellows pump 27, at the time when the first processing liquid reaches the bellows pump 27, so that the first processing liquid is fed under pressure in the forward direction. Further, the controller 73 maintains the control valve 23 and the control valve 29 in the open state. With this, the controller 73 circulates the first processing liquid in the forward direction from the outer tank 5 to the inner tank 3 via the circulation pipe 21. In this case, the first filter 55 collects a foreign matter in the first processing liquid. The forward direction in the circulation processing step (S3) which forward direction is illustrated in FIG. 5 is a path indicated by a solid line arrow.

After the circulation processing step (S3), the controller 73 carries out a substrate processing step (S4) illustrated in FIG. 3. In the substrate processing step (S4), the controller 73 controls the lifter 11. In the substrate processing step (S4), the controller 73 controls the lifter 11 so as to move the substrate W to the processing position. Thus, the lifter 11 immerses the substrate W in the first processing liquid, and the first processing liquid carries out processing with respect to the substrate W. Upon completion of processing of the substrate W by the first processing liquid, the controller 73 controls the lifter 11, and the lifter 11 moves the substrate W to the waiting position.

Further, in the present embodiment, the second-second supply valve 69, the second supply valve 87, and the second discharge valve 65 are opened in the circulation processing step (S3) as illustrated in FIG. 4. This causes the second processing liquid to flow from the second processing liquid supply section 47 into the second branch pipe 41 in the backward direction.

Further, in the substrate processing step (S4), as illustrated in FIGS. 4 and 5, after closing the second-second supply valve 69, the controller 73 carries out control so as to open the second-third supply valve 85, the second supply valve 87, and the second discharge valve 65. This causes the third processing liquid to flow from the third processing liquid supply section 48 into the second branch pipe 41 in the backward direction along a path indicated by dash-dot arrows in FIG. 5.

More specifically, in a state in which the first circulation valves 49 and 51 are opened and the second circulation valves 67 and 71 are closed, the controller 73 controls the bellows pump 27 such that the processing liquid is fed under pressure from the outer tank 5 to the inner tank 3 via the circulation pipe 21 in the forward direction. Further, the controller 73 carries out control so as to open the second-second supply valve 69 for a prescribed period. Such control causes the second processing liquid to flow from the second processing liquid supply section 47 into the second branch pipe 41 in the backward direction. Thereafter, the controller 73 carries out control so as to close the second-second supply valve 69 and open the second-third supply valve 85 for a prescribed period. Such control causes the third processing liquid to flow from the third processing liquid supply section 48 into the second branch pipe 41 in the backward direction. That is, the controller 73 carries out a filter cleaning step (second cleaning process) described later with respect to the second filter 57 during a period in which the first processing liquid is circulated in the first branch pipe 38. In other words, the controller 73 carries out the second cleaning process with respect to the second filter 57 during a period in which the first switching section 25 is controlled so as to allow the first processing liquid to flow into the first branch pipe 38 in the forward direction.

In the present embodiment, the second processing liquid supply section 47 supplies the second processing liquid to the second filter 57 in the circulation processing step (S3). Further, in the substrate processing step (S4), the third processing liquid supply section 48 supplies the third processing liquid to the second filter 57. However, the present invention is not limited to this. In the circulation processing step (S3), the second processing liquid supply section 47 and the third processing liquid supply section 48 may sequentially supply the second processing liquid and the third processing liquid, respectively. Alternatively, in the substrate processing step (S4), the second processing liquid supply section 47 and the third processing liquid supply section 48 may sequentially supply the second processing liquid and the third processing liquid, respectively.

Note that a case is considered where the second filter 57 serving as the waiting filter is unused at the time when the controller 73 carries out the circulation processing step (S3) and the substrate processing step (S4) first. In this case, in the circulation processing step (S3) and the substrate processing step (S4) immediately after the start of the operation of the substrate processing apparatus 100, the controller 73 need not carry out the foregoing filter cleaning process with respect to the second filter 57 serving as the waiting filter. In this case, the controller 73 preferably causes not only the first filter 55 but also the second filter 57 to be filled with the first processing liquid or the third processing liquid at the time when the substrate processing apparatus 100 starts processing with respect to the substrate W. This makes it possible for the controller 73 to quickly start using the second filter 57 as the processing filter after a filter switching step (described later).

Regarding a prescribed period during which the second-second supply valve 69 is opened and a prescribed period during which the first-second supply valve 63 is opened, a period sufficient for a designer or a user of the substrate processing apparatus 100 to clean the filter 53 may be set as appropriate. Regarding a prescribed period during which the second-third supply valve 85 is opened and a prescribed period during which the first-third supply valve 81 is opened, a period sufficient for the designer or the user of the substrate processing apparatus 100 to fill the filter 53 and its vicinity with the third processing liquid may be set as appropriate.

In the circulation processing step (S3), on the basis of a value detected by the stroke sensor 75 included in the bellows pump 27 (described earlier), the controller 73 can detect a liquid transport time, which is a time required for the bellows pump 27 to feed a liquid under pressure.

After the substrate processing step (S4), the controller 73 carries out a switching processing step (S5) illustrated in FIG. 3. Specifically, the controller 73 carries out a lot processing determination step (S51), a switch condition determination step (S52), and a filter switching step (S53) in the switching processing step (S5).

In the lot processing determination step (S51), the controller 73 determines, for processing of the substrate W, whether processing of one lot has ended. In a case where processing of the lot has not ended (NO in S51), the controller 73 repeats step S41 until processing of the lot ends. In a case where processing of the lot has ended (YES in S51), the controller 73 carries out the switch condition determination step (S52).

In the switch condition determination step (S52), the controller 73 determines whether a switch condition, which is a condition for switching each of the processing filter and the waiting filter from one of the first filter 55 and the second filter 57 to the other, has been satisfied. In a case where the switch condition has not been satisfied (NO in S52), the controller 73 skips the filter switching step (S53) of step S5, step S6, and step S7 and carries out a completion confirmation step (S8). Details of the completion confirmation step (S8) will be described later.

In a case where the switch condition has been satisfied (YES in S52), the controller 73 carries out the filter switching step (S53) (described later). The switch condition can be, for example, a liquid transport time, the number of lots, a processing period, or a recipe.

In a case where the switch condition is a liquid transport time, the switch condition is such that the liquid transport time of the bellows pump 27 which liquid transport time is derived from output of the stroke sensor 75 is not less than a prescribed threshold value. In a case where the switch condition is the number of lots, the switch condition is, for example, such that processing is carried out with respect to a prescribed number of lots for the substrate W. In a case where the switch condition is a processing period, the switch condition is, for example, such that processing has been carried out over a prescribed period. In a case where the switch condition is a recipe, for example, a recipe that is prescribed for the operation of the substrate processing apparatus 100 is configured to switch, before processing of the lot is started, the filter 53 which is used to filter the first processing liquid.

In the lot processing determination step (S51) and the switch condition determination step (S52), open/closed states of the valves are similar to those in the substrate processing step (S3) and the circulation processing step (S4). Note that a description of the switching processing step (S5) in FIG. 4 is a timing chart showing the open/closed states of the valves in a case where the filter switching step (S53) is carried out.

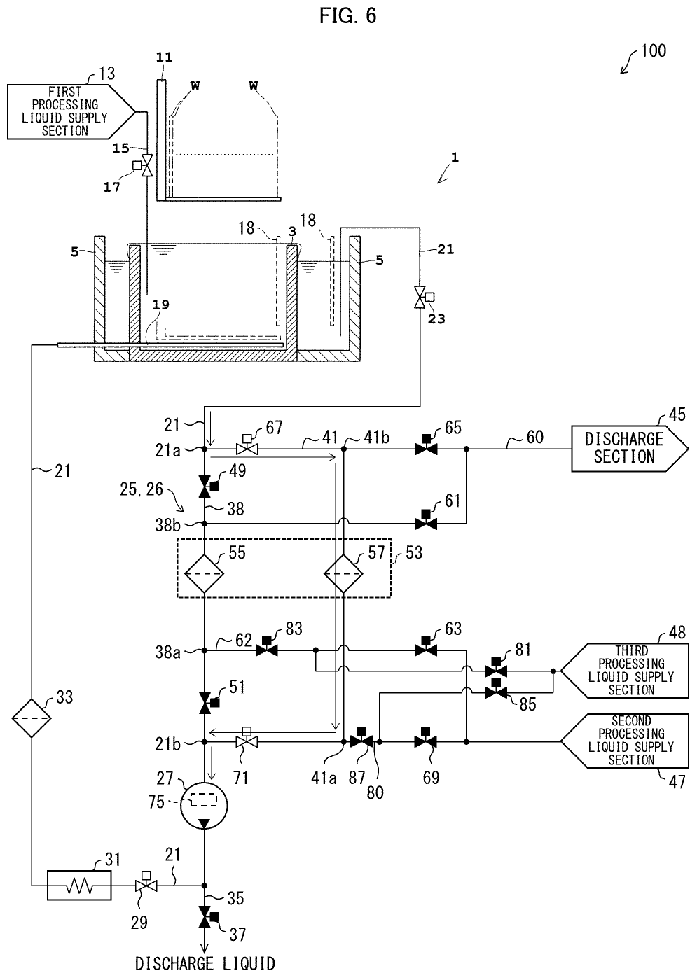

In the filter switching step (S53), by controlling the first switching section 25, the controller 73 switches a circulation path along which the first processing liquid flows in the circulation pipe 21 in the forward direction. In the present description, as illustrated in FIG. 6, the controller 73 switches the circulation path, along which the first processing liquid flows in the forward direction, from the first branch pipe 38 provided with the first filter 55, which is the processing filter, to the second branch pipe 41 provided with the second filter 57, which is the waiting filter. More specifically, as illustrated in FIGS. 4 and 6, the controller 73 switches the first circulation valves 49 and 51 from the open state to the closed state and switches the second circulation valves 67 and 71 from the closed state to the open state.

In the filter switching step (S53), while switching the first circulation valves 49 and 51 to the closed state and switching the second circulation valves 67 and 71 to the open state, the controller 73 switches the processing filter and the waiting filter that have been selected in the filter selection step (S1). More specifically, among the filters 53, the controller 73 selects, as the waiting filter, the first filter 55 that has been selected as the processing filter in the filter selection step (S1), and selects, as the processing filter, the second filter 57 that has been selected as the waiting filter in the filter selection step (S1). The controller 73 temporarily stores, in the memory 732 of the controller 73, filter selection information pertaining to the filter 53 selected as each of the processing filter and the waiting filter.

After the switching processing step (S5), the controller 73 carries out a filter preparation step (S6) illustrated in FIG. 3. Specifically, the controller 73 carries out a first processing liquid flow step (S61) and a first processing liquid temperature determination step (S62) in the filter preparation step (S6).

The first processing liquid flow step (S61) is carried out simultaneously with or after the filter switching step (S53). In the filter switching step (S53), by controlling the first switching section 25, the controller 73 switches the circulation path along which the first processing liquid flows in the circulation pipe 21 in the forward direction. Specifically, as described earlier, the controller 73 closes the pair of first circulation valves 49 and 51 and opens the pair of second circulation valves 67 and 71. With this, the controller 73 causes the first processing liquid to flow into the second branch pipe 41. The first processing liquid flow step (S61) starts a period in which the first switching section 25 is controlled by the controller 73 so as to allow the first processing liquid to flow into the second branch pipe 41 in the forward direction. Thus, the first processing liquid flows, along a path indicated by solid line arrows in FIG. 6, into the second filter 57, which is the processing filter. Further, a foreign matter is collected by the first processing liquid being filtered by the second filter 57.

After the first processing liquid flow step (S61), the controller 73 carries out the first processing liquid temperature determination step (S62) of determining whether the temperature of the first processing liquid in the inner tank 3 has been stabilized. Specifically, after switching the filter 53 that is used to filter the first processing liquid, the controller 73 determines whether the temperature of the first processing liquid in the inner tank 3 has been stabilized. Immediately after the filter 53 is switched, the third processing liquid in the filter 53 is mixed with the first processing liquid. This makes unstable the temperature of the first processing liquid in the inner tank 3. For example, in a case where the temperature of the first processing liquid in the inner tank 3 is in a range of +5° C. from a reference temperature, the controller 73 may determine that the temperature of the first processing liquid in the inner tank 3 is stable.

In a case where the temperature of the first processing liquid is unstable (NO in S62), the controller 73 repeats step S62 until the temperature of the first processing liquid is stabilized. More specifically, in a case where it is determined that the temperature of the first processing liquid in the inner tank 3 is unstable, the controller 73 may wait for a prescribed time and then carry out determination again for the temperature of the first processing liquid in the inner tank 3. In this case, the prescribed time may be, for example, 3 minutes. However, a method in which the controller 73 determines whether the temperature of the first processing liquid in the inner tank 3 has been stabilized, and a waiting time until determination is carried out again in case where the temperature is unstable are not limited to the above-described examples. In a case where the temperature of the first processing liquid has been stabilized (YES in S62), the controller 73 carries out a filter cleaning step (S7) (described later).

After the filter preparation step (S6), the controller 73 subjects the first filter, which is the waiting filter, to the filter cleaning step (first cleaning process) (S7) illustrated in FIG. 3. Specifically, the controller 73 carries out a second processing liquid supply step (S71) and a third processing liquid supply step (S72) in the filter cleaning step (S7).

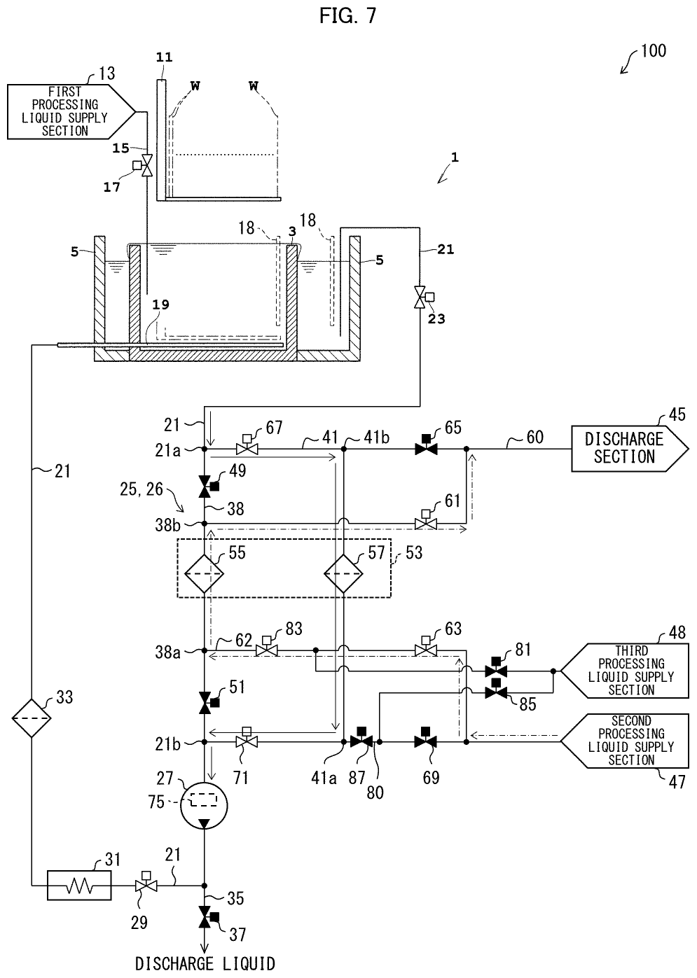

In the second processing liquid supply step (S71), the controller 73 controls the second switching section 26 so as to (i) allow the second processing liquid to flow into the first branch pipe 38 in the backward direction and (ii) cause a liquid containing at least the first processing liquid to be discharged from the discharge section 45. Specifically, as illustrated in FIGS. 4 and 7, while allowing the first processing liquid to flow into the second branch pipe 41 by closing the first circulation valves 49 and 51 and opening the second circulation valves 67 and 71, the controller 73 opens the first supply valve 83, closes the second supply valve 87, opens the first discharge valve 61, and closes the second discharge valve 65. Further, the controller 73 opens the first-second supply valve 63, opens the first supply valve 83, and opens the first discharge valve 61. Thus, the second processing liquid flows from the second processing liquid supply section 47 into the first branch pipe 38 along a flow indicated by dash-dot arrows in FIG. 7.

The discharge pipe 60 branches off from the first branch pipe 38 at the fifth branch point 38b located on the upstream side of the first filter 55. Thus, in the second processing liquid supply step (S71), the second processing liquid flows from the second processing liquid supply section 47 into the first branch pipe 38 from the backward direction, so that the liquid containing at least the first processing liquid flows through the discharge pipe 60 and is discharged from the discharge section 45. Thus, at least a part of the first processing liquid present inside the filter 53 is replaced with the second processing liquid. In the second processing liquid supply step (S71), clogging of the filter 53 can be removed by the second processing liquid flowing into the filter 53 from the backward direction. Note here that the second processing liquid is preferably a liquid which is suitable for removing clogging of the filter 53. It is most desirable to replace all of the first processing liquid present inside the filter 53 with the second processing liquid.

Further, as described earlier, the circulation pipe 21 further includes the heater 31 that heats the first processing liquid to the prescribed temperature. In contrast, the second processing liquid supply section 47 supplies the second processing liquid at normal temperature. The term “normal temperature” as used herein is in a range of, for example, 5° C. to 35° C.

For example, in a case where the first processing liquid is a processing liquid containing sulfuric acid or is phosphoric acid, the controller 73 preferably uses the heater 31 to cause the first processing liquid to be at a temperature higher than normal temperature. In contrast, in a case where the second processing liquid is pure water or a processing liquid containing hydrofluoric acid, the controller 73 preferably causes the second processing liquid to be at normal temperature. The substrate processing apparatus 100 makes it possible to also address a case where the first processing liquid and the second processing liquid thus differ in preferable temperature. Further, as described earlier, the third processing liquid that is a liquid which does not bump even when mixed with the first processing liquid makes it possible to prevent or reduce occurrence of a problem in a case where circulation of the first processing liquid in the circulation pipe 21 is resumed. However, the second processing liquid supply section 47 does not necessarily need to supply the second processing liquid at normal temperature, and may supply the second processing liquid that is at a high temperature.

Immediately after the second processing liquid supply section 47 supplies the second processing liquid to the first branch pipe 38, the first filter 55 and its vicinity are filled with the second processing liquid. If the controller 73 resumes circulation of the first processing liquid in the circulation pipe 21 in this state, the first processing liquid and the second processing liquid are mixed in the circulation pipe 21. In this case, assume, for example, that the first processing liquid is at a high temperature and a boiling point of the second processing liquid is lower than the temperature of the first processing liquid. In this case, a problem such as damage to, for example, a pipe of the inner tank 3 may occur due to occurrence of bumping in the second processing liquid.

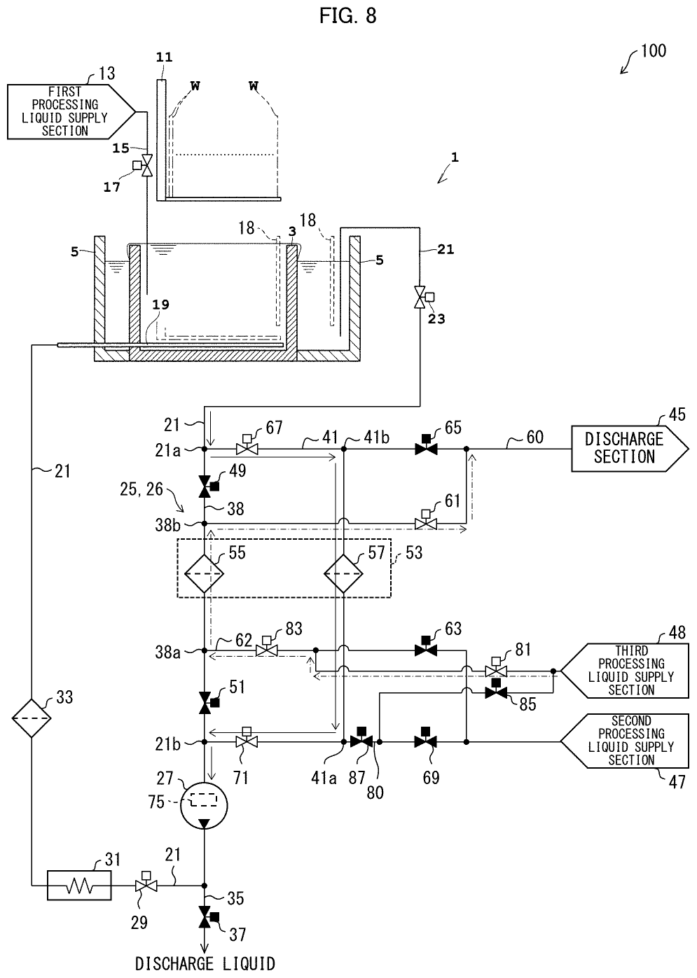

In order to address such a problem, the controller 73 carries out the third processing liquid supply step (S72) in the filter cleaning step (S7). In the third processing liquid supply step (S72), the controller 73 controls the second switching section 26 so as to (i) allow the third processing liquid to flow into the first branch pipe 38 in the backward direction and (ii) cause a liquid containing at least the second processing liquid to be discharged from the discharge section 45. Specifically, as illustrated in FIGS. 4 and 8, in a state in which the first circulation valves 49 and 51 are closed, the controller 73 carries out control so as to open the second circulation valves 67 and 71, open the first-third supply valve 81, open the first supply valve 83, and open the first discharge valve 61. Thus, the third processing liquid flows from the third processing liquid supply section 48 into the first branch pipe 38 along a flow indicated by dash-dot arrows in FIG. 8.

The controller 73 carries out control such that, in a state in which the second circulation valves 67 and 71 are opened and the first circulation valves 49 and 51 are closed, the first-second supply valve 63 is opened for a prescribed period, then the first-second supply valve 63 is closed, and the first-third supply valve 81 is opened for a prescribed period. This makes it possible to appropriately carry out control for cleaning the first filter 55 during a period in which the first processing liquid is circulated in the second branch pipe 41. In other words, the controller 73 carries out a first cleaning process with respect to the first filter 55 during a period in which the first processing liquid is circulated in the second branch pipe 41.

Regarding a prescribed period during which the controller 73 opens the first-second supply valve 63 and the first-third supply valve 81, a period sufficient for the designer or the user of the substrate processing apparatus 100 to clean the filter 53 may be set as appropriate.

In the third processing liquid supply step (S72), the third processing liquid flows from the third processing liquid supply section 48 into the first filter 55 from the backward direction, so that the liquid containing at least the second processing liquid is discharged from the discharge section 45. Thus, at least a part of the second processing liquid present inside the first filter 55 is replaced with the third processing liquid. The third processing liquid flowing through the first filter 55 causes the third processing liquid to remain in the first filter 55. Occurrence of a problem in a case where circulation of the first processing liquid in the circulation pipe 21 is resumed can be prevented or reduced by replacing, with the third processing liquid that does not bump even when mixed with the first processing liquid, at least a part of the second processing liquid remaining inside the first filter 55. Note that all of the second processing liquid inside the first filter 55 is most preferably replaced with the third processing liquid. In the third processing liquid supply step (S72), clogging of the first filter 55 can be removed by causing the third processing liquid to flow backward with respect to the first filter 55.

In the substrate processing apparatus 100, as described earlier, the upflow pipe 19 is made of a material containing quartz. Such an upflow pipe 19 is highly likely to be damaged in a case where bumping occurs in the circulation pipe 21. However, the third processing liquid that is a liquid which does not bump even when mixed with the first processing liquid makes it possible to prevent or reduce occurrence of a problem of damage to the upflow pipe 19 in a case where circulation of the first processing liquid in the circulation pipe 21 is resumed.

For example, in a case where a component of the second processing liquid greatly differs from a component of the first processing liquid, mixing of the second processing liquid and the first processing liquid may cause such a problem that the component of the first processing liquid is in a state unsuitable for processing of the substrate W by the substrate process tank 1. In the substrate processing apparatus 100, occurrence of the above-described problem in a case where circulation of the first processing liquid in the circulation pipe 21 is resumed can be prevented or reduced by the third processing liquid being a liquid in which the component of the first processing liquid shows less change even in a case where the liquid is mixed with the first processing liquid.

That is, the substrate processing apparatus 100 not only allows the second processing liquid to be a liquid that is suitable for cleaning the filter 53, but also allows the third processing liquid to be a liquid in which occurrence of a problem is prevented or reduced even in a case where the liquid is mixed with the first processing liquid. This makes it possible to appropriately and safely clean the filter 53.

In particular, the first processing liquid is sometimes a processing liquid containing sulfuric acid and a hydrogen peroxide solution. In this case, in the first processing liquid, water is generated by autolysis of the hydrogen peroxide solution and a reaction of the hydrogen peroxide solution with the sulfuric acid. This results in a decrease in concentration of the sulfuric acid in the first processing liquid over time. By using sulfuric acid as the third processing liquid as sulfuric acid, it is possible to increase the decreased concentration of the sulfuric acid in a case where the third processing liquid and the first processing liquid are mixed. Thus, in such a case, mixing of the third processing liquid and the first processing liquid brings the component of the first processing liquid that circulates in the circulation pipe 21 into a state suitable for processing by the substrate process tank 1.

After the filter cleaning step (S7), the controller 73 carries out the completion confirmation step (S8). In the filter cleaning step (S7), the controller 73 determines whether there is any lot to process next. In a case where there is no lot to process next (NO in S8), the controller 73 ends the operation of the substrate processing apparatus 100. In a case where there is a lot to process next (YES in S8), the controller 73 carries out the foregoing circulation processing step (S3) again. Note that, since the filter cleaning step (S7) is carried out, the foregoing cleaning process with respect to the waiting filter is not carried out in the circulation processing step (S3) and the substrate processing step (S4) that are carried out again after the completion confirmation step (S8).

Next, the processing resumption step (S9) will be described by taking, as an example, a case where in the completion confirmation step (S8), there is a lot to process next (YES in S8). The processing resumption step (S9) is a step of, after the filter cleaning step (S7), allowing the first processing liquid to flow into the filter 53 in the forward direction. In other words, the processing resumption step (S9) is the filter preparation step (S6) that is carried out again in a case where in the completion confirmation step (S8), there is a lot to process next (YES in S8). In order to avoid duplication, a description of the circulation processing step (S3), the substrate processing step (S4), and the lot processing determination step (S51) and the switch condition determination step (S52) of the switching processing step (S5) among the steps that are carried out again in a case where in the completion confirmation step (S8), there is a lot to process next (YES in S8) is omitted here. The following description is premised on a case where the second filter 57 is used as the processing filter in the circulation processing step (S3) and the substrate processing step (S4), lot processing ends in the lot processing determination step (S51), and the switch condition is satisfied in the switch condition determination step (S52) (YES in S51 and YES in S52).

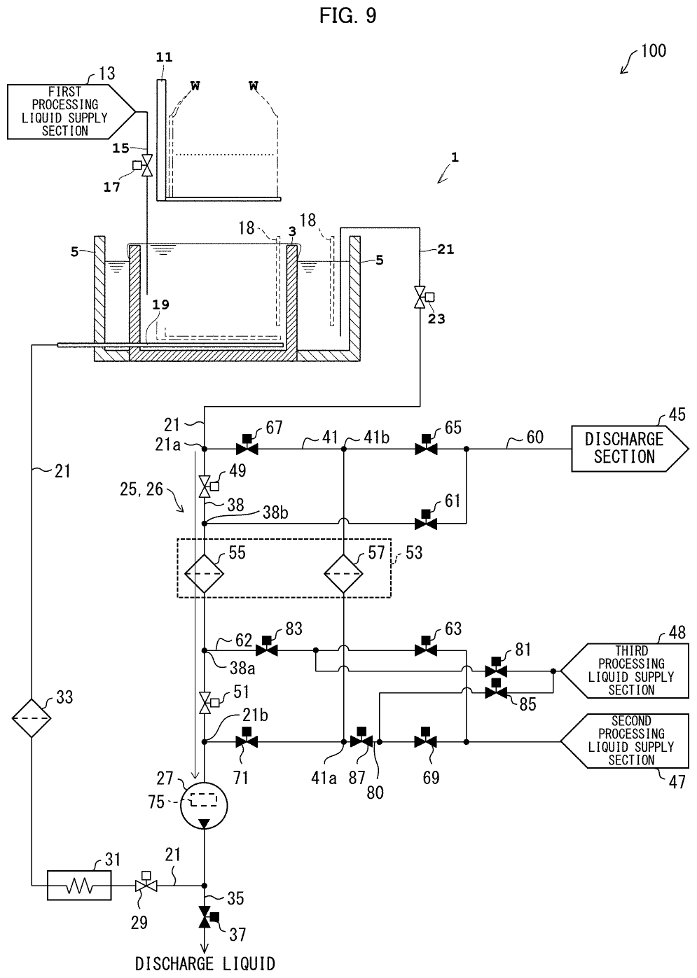

In the filter switching step (S53), by controlling the first switching section 25, the controller 73 switches a circulation path along which the first processing liquid flows in the circulation pipe 21 in the forward direction. In the present description, as illustrated in FIG. 9, the controller 73 switches the circulation path, along which the first processing liquid flows in the forward direction, from the second branch pipe 41 provided with the second filter 57, which is the processing filter, to the first branch pipe 38 provided with the first filter 55, which is the waiting filter. More specifically, as illustrated in FIGS. 4 and 9, the controller 73 switches the first circulation valves 49 and 51 from the closed state to the open state and switches the second circulation valves 67 and 71 from the open state to the closed state.

Next, the controller 73 carries out the second first processing liquid flow step (S61) and the second first processing liquid temperature determination step (S62) in the filter preparation step (S6).

The controller 73 carries out the first processing liquid flow step (S61) after the filter switching step (S53). In the filter switching step (S53), by controlling the first switching section 25, the controller 73 switches a circulation path along which the first processing liquid flows in the circulation pipe 21 in the forward direction. Thus, the first processing liquid flows, along a path indicated by a solid line arrow in FIG. 9, into the first filter 55, which is the processing filter. In other words, the controller 73 circulates the first processing liquid to the first filter 55 in the forward direction after the filter switching step (S53).

After the first processing liquid flow step (S61), the controller 73 carries out the first processing liquid temperature determination step (S62) of determining whether the temperature of the first processing liquid in the inner tank 3 has been stabilized. In the present embodiment, in the foregoing second first processing liquid flow step (S61) and the foregoing second first processing liquid temperature determination step (S62), the first processing liquid is circulated in the forward direction to the first filter 55 that has been subjected to the filter cleaning step (S7). Thus, the foregoing second first processing liquid flow step (S61) and the foregoing second first processing liquid temperature determination step (S62) correspond to the processing resumption step (S9).

Content of the filter cleaning step (S7) carried out by the controller 73 after the processing resumption step (S9) illustrated in FIG. 4 is as described in the foregoing first description of the circulation processing step (S3) and the substrate processing step (S4). The completion confirmation step (S8) is also as described earlier.

As described above, in the substrate processing method carried out in the substrate processing apparatus 100, the filter cleaning step (S7) is carried out by the second processing liquid supply step (S71) and the third processing liquid supply step (S72). Furthermore, the first processing liquid is circulated to the filter 53 in the forward direction by the processing resumption step (S9) after the filter cleaning step (S7). With this, as described earlier, it is possible to prevent or reduce a problem caused by mixing of the first processing liquid and the second processing liquid.

Further, in the processing resumption step (S9), a period in which the first switching section 25 is controlled by the controller 73 so as to allow the first processing liquid to flow into the first branch pipe 38 in the forward direction is started. The controller 73 carries out the filter cleaning step (S7) (second cleaning process) with respect to the second filter 57 during the period. In the second cleaning process, the controller 73 controls the second switching section 26 so as to (i) allow the second processing liquid to flow into the second branch pipe 41 in the backward direction and (ii) cause the liquid containing at least the first processing liquid to be discharged from the discharge section 45. Thereafter, the controller 73 further controls the second switching section 26 so as to (iii) allow the third processing liquid to flow into the second branch pipe 41 in the backward direction and (iv) cause the liquid containing at least the second processing liquid to be discharged from the discharge section 45. Further, in the processing resumption step (S9) after the second cleaning process, the controller 73 allows the first processing liquid to flow into the second branch pipe 41 in the forward direction.

### Embodiment 2

Another embodiment of the present invention will be described below. Embodiment 2 differs from Embodiment 1 in that Embodiment 2 includes a third processing liquid supply section 48A instead of the third processing liquid supply section 48 of Embodiment 1 and in that a third processing liquid supply step (S152) is carried out after a switch condition determination step (S151). Note that for convenience, members having functions identical to those of the respective members described in Embodiment 1 are given respective identical reference signs, and a description of those members is omitted.

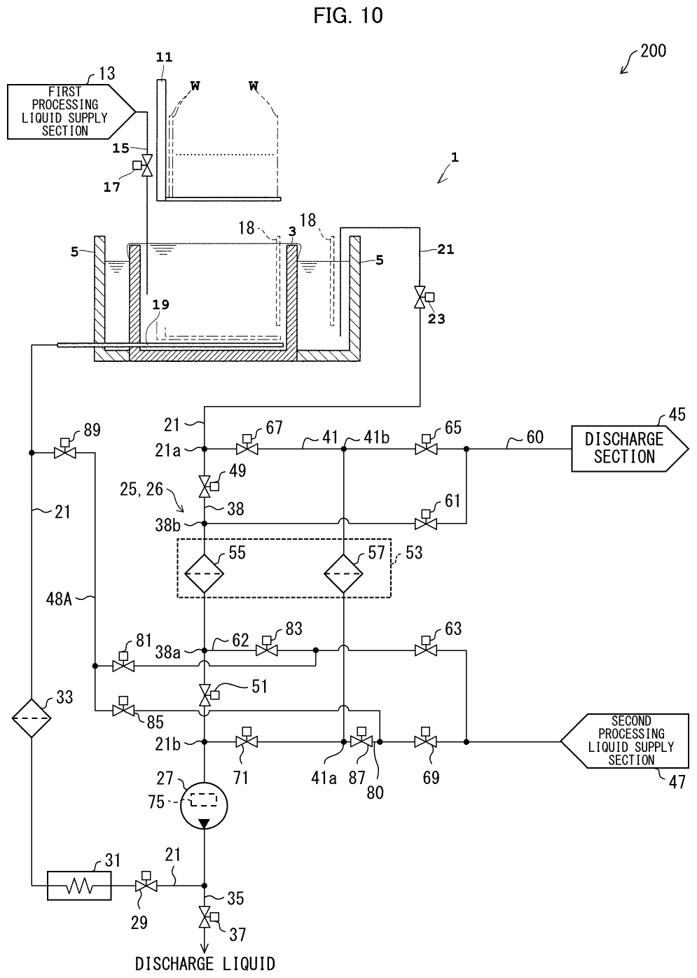

FIG. 10 is an overall view schematically illustrating a configuration of a substrate processing apparatus 200 in accordance with Embodiment 2.

The third processing liquid supply section 48A is a flow path that connects a circulation pipe 21 between a main filter 33 and an inner tank 3 and a filter 53. The third processing liquid supply section 48A supplies a third processing liquid to the filter 53 by branching off from the circulation pipe 21. In the substrate processing apparatus 200, the third processing liquid is a first processing liquid that circulates in the circulation pipe 21. This allows a change in state of the first processing liquid that circulates in the circulation pipe 21 to be very small at a timing at which circulation of the first processing liquid in the circulation pipe 21 is resumed after a cleaning process ends. It is therefore possible to make extremely short a time required to resume processing of a substrate W after the filter 53 that is used to filter the first processing liquid is switched.

The third processing liquid supply section 48A includes a third supply valve 89. The third supply valve 89 controls supply of the first processing liquid to the filter 53. The third processing liquid supply section 48A supplies the first processing liquid to the filter 53 at a flow rate lower than a flow rate at which the first processing liquid overflows from the inner tank 3 to an outer tank 5. Thus, even in a case where the first processing liquid that circulates in the circulation pipe 21 is supplied to the filter 53 which is being subjected to the cleaning process, it is possible to reliably secure the first processing liquid in an amount necessary for processing in a substrate process tank 1.

In the substrate processing apparatus 200, in a filter cleaning process, by controlling a first switching section 25, a controller 73 supplies the third processing liquid to a second filter 57 immediately before an end of a period in which the first processing liquid is circulated in a first branch pipe 38. Further, by controlling the first switching section 25, the controller 73 supplies the third processing liquid to a first filter 55 immediately before an end of a period in which the first processing liquid is circulated in a second branch pipe 41. Note that the controller 73 may supply the third processing liquid to the filter 53 at a timing, which is immediately before the end of the period in which the first processing liquid is circulated in the second branch pipe 41, also in the substrate processing apparatus 100 including the third processing liquid supply section 48 instead of the third processing liquid supply section 48A.

Thus, immediately before an end of a period in which the first processing liquid is circulated in one branch pipe among the first branch pipe 38 and the second branch pipe 41, the controller 73 causes the third processing liquid supply section 48 to supply the third processing liquid to the filter 53 of the other branch pipe. This makes it possible to minimize an amount of the third processing liquid supplied to the filter 53 in the filter cleaning process.

In particular, in the substrate processing apparatus 200, as described above, to the filter 53, the controller 73 supplies, as the third processing liquid, the first processing liquid that circulates in the circulation pipe 21. Thus, minimizing the amount of the third processing liquid supplied to the filter 53 makes it possible to minimize an amount of a decrease in first processing liquid that circulates in the circulation pipe 21.

For example, the controller 73 supplies the filter 53 that is waiting with a second processing liquid until a switch condition (described earlier) is satisfied, and supplies the third processing liquid in a case where the switch condition has been satisfied. Thereafter, the controller 73 ends supply of the third processing liquid and switches the branch pipe in which the first processing liquid circulates to the branch pipe including the filter 53 that was waiting until then.

In this case, for cleaning of the substrate w, processing of one lot need not have ended by the time when supply of the third processing liquid is started after the switch condition is satisfied. In a case where processing of one lot has not ended by the time when the branch pipe in which the first processing liquid circulates is switched after end of supply of the third processing liquid, the controller 73 waits until processing of one lot ends. In a case where processing of one lot has ended before supply of the third processing liquid to the filter 53 after the switch condition is satisfied, the controller 73 may wait for processing of a subsequent lot until end of switching of the branch pipe in which the first processing liquid circulates. Such switching of the branch pipe in which the first processing liquid circulates and such waiting for processing of a subsequent lot are omitted in a flowchart (described later).

### (Operation)

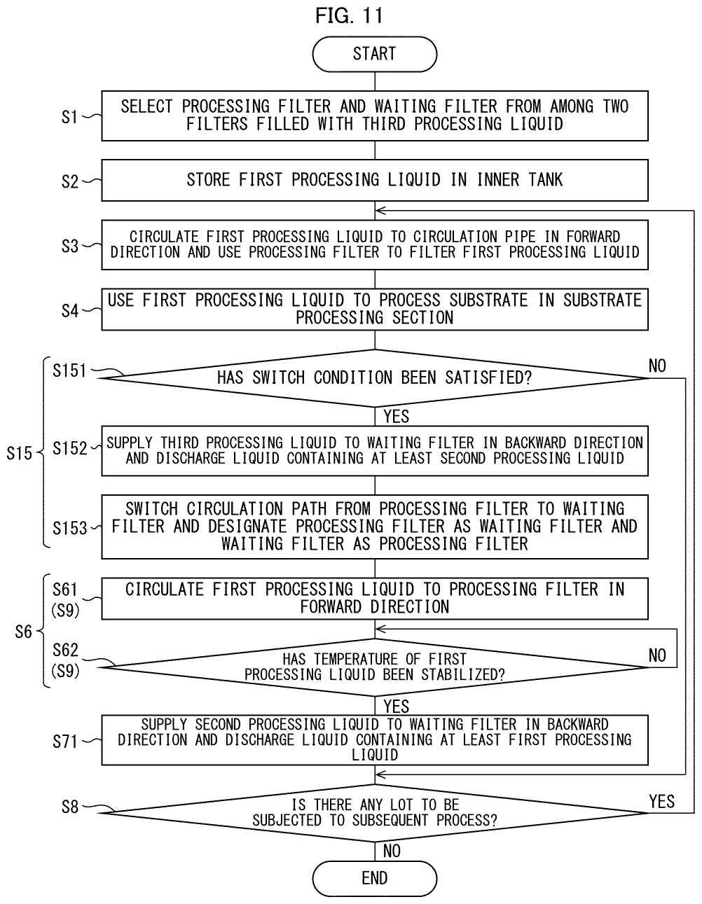

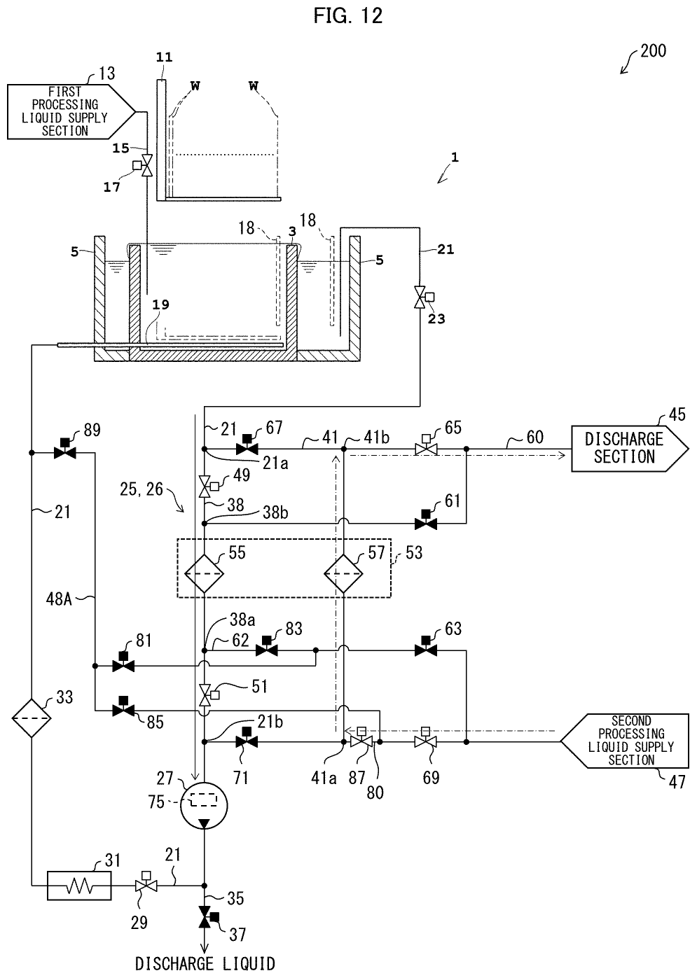

An operation of the substrate processing apparatus 200 will be described with reference to FIGS. 11 to 15. FIG. 11 is a flowchart illustrating the operation of the substrate processing apparatus 200. FIGS. 12 to 15 are diagrams illustrating open/closed states of valves of the first switching section 25 and a second switching section 26. In FIGS. 12 to 15, a valve that is among the valves of the first switching section 25 and the second switching section 26 and that is closed is illustrated in black.

In the substrate processing apparatus 200, the controller 73 carries out a filter selection step (S1), a first processing liquid storage step (S2), a circulation processing step (S3), and a substrate processing step (S4). Since these steps are identical to those in the substrate processing apparatus 100, a description thereof is omitted here. The following description takes, as an example, a case where the first filter 55 and the second filter 57 are selected as a processing filter and a waiting filter, respectively, in the filter selection step (S1). For this reason, in the substrate processing step (S4), as illustrated in FIG. 12, the controller 73 opens first circulation valves 49 and 51 and closes second circulation valves 67 and 71.

However, in the first circulation processing step (S3) and the first substrate processing step (S4), only the second processing liquid is supplied to the second filter 57 in a backward direction, and the third processing liquid is not supplied. In other words, at least a part of the first processing liquid is replaced by the second processing liquid being supplied to the second filter 57, and the second processing liquid remains in the second filter 57. Thus, in the substrate processing step (S4), a second-second supply valve 69, a second supply valve 87, and a second discharge valve 65 are opened as illustrated in FIG. 12.

After the substrate processing step (S4), the controller 73 carries out a switching processing step (S15) illustrated in FIG. 11. Specifically, the controller 73 carries out the switch condition determination step (S151), the third processing liquid supply step (S152), and a filter switching step (S153) in the switching processing step (S15).

In the switch condition determination step (S151), the controller 73 determines whether the switch condition has been satisfied. In a case where the switch condition has not been satisfied (NO in S151), the controller 73 skips the third processing liquid supply step (S152) and the filter switching step (S153) of step S15, step S6, and step S71 and carries out a completion confirmation step (S8).

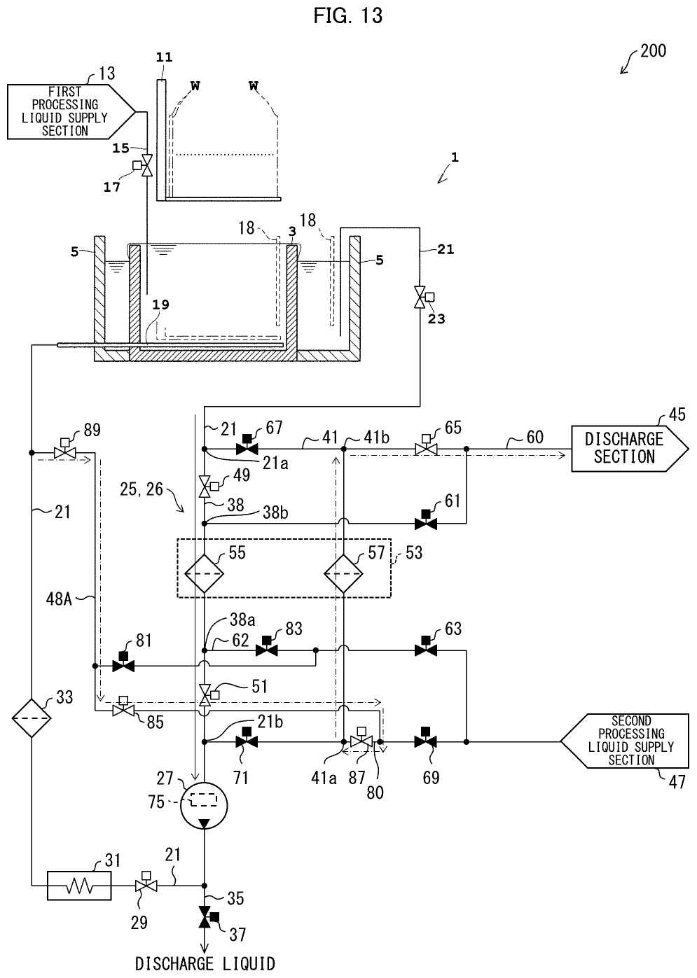

In a case where the switch condition has been satisfied (YES in S151), the controller 73 carries out the third processing liquid supply step (S152). In the third processing liquid supply step (S152), the controller 73 supplies the third processing liquid to the second filter 57, which is the waiting filter, from the backward direction. Specifically, the controller 73 opens the third supply valve 89, the second supply valve 87, and the second discharge valve 65 as illustrated in FIG. 13. Thus, the third processing liquid flows from the third processing liquid supply section 48A into the second branch pipe 41 along a flow indicated by dash-dot arrows in FIG. 13.

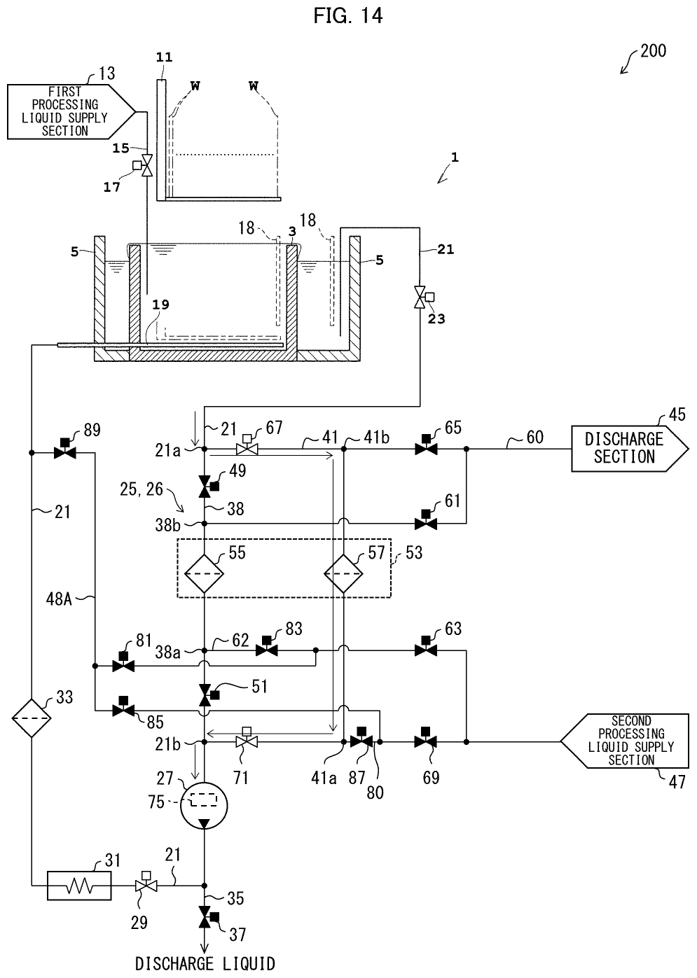

The controller 73 carries out the filter switching step (S153) after the third processing liquid supply step (S152). In the filter switching step (S153), by controlling the first switching section 25, the controller 73 switches a circulation path along which the first processing liquid flows in the circulation pipe 21 in the forward direction. In the present description, as illustrated in FIG. 14, the controller 73 switches the circulation path, along which the first processing liquid flows in the forward direction, from the first branch pipe 38 provided with the first filter 55, which is the processing filter, to the second branch pipe 41 provided with the second filter 57, which is the waiting filter.

After the switching processing step (S15), the controller 73 carries out a filter preparation step (S6) illustrated in FIG. 11. Since the filter preparation step (S6) is identical to that in the substrate processing apparatus 100, a description thereof is omitted here.

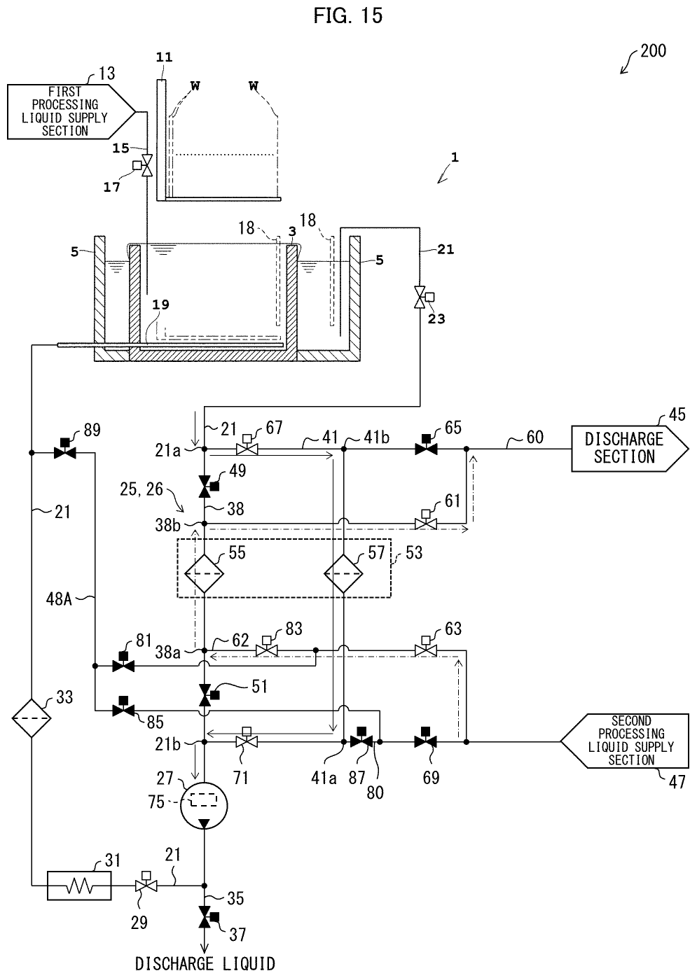

The controller 73 carries out a second processing liquid supply step (S71) after the filter preparation step (S6). In the second processing liquid supply step (S71), the controller 73 supplies the second processing liquid to the first filter 55, which is the waiting filter, from the backward direction. Specifically, as illustrated in FIG. 15, in a state in which the first circulation valves 49 and 51 are closed, the controller 73 carries out control so as to open a first-second supply valve 63, open a first supply valve 83, and open a first discharge valve 61. Thus, the second processing liquid flows from the second processing liquid supply section 47 into the first branch pipe 38 along a flow indicated by dash-dot arrows in FIG. 15.

The controller 73 carries out the completion confirmation step (S8) after the second processing liquid supply step (S71). Since the completion confirmation step (S8) is identical to that in the substrate processing apparatus 100, a description thereof is omitted here.

Since a processing resumption step (S9) is identical to that in the substrate processing apparatus 100, a detailed description thereof is omitted here. In the processing resumption step (S9), supply of the first processing liquid to the filter 53 in the forward direction is resumed. In Embodiment 2, in the filter switching step (S153), the first processing liquid is supplied in the forward direction to the second filter 57 that has been switched from the waiting filter to the processing filter and that is filled with a liquid containing at least the second processing liquid.

As described above, in a substrate processing method carried out in the substrate processing apparatus 200, the controller 73 carries out the third processing liquid supply step (S152) with respect to the waiting filter after it is determined in the switch condition determination step (S151) that the switch condition has been satisfied. Further, after carrying out the second processing liquid supply step (S71) with respect to the filter 53 that has been set as the waiting filter in the filter switching step (S153), without supplying the third processing liquid to the filter 53, the controller 73 causes the filter 53 to wait. Thus, as described earlier, it is possible to minimize an amount of the third processing liquid supplied to the filter 53 in the filter cleaning process.

### Embodiment 3

Still another embodiment of the present invention will be described below.

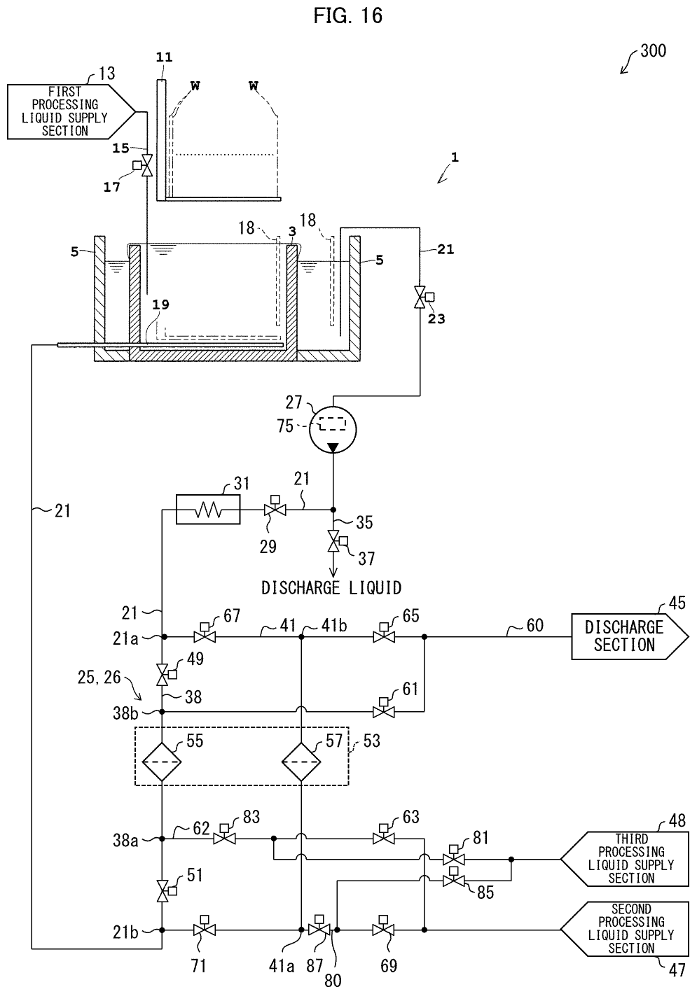

FIG. 16 is an overall view schematically illustrating a configuration of a substrate processing apparatus 300 in accordance with Embodiment 3. In the substrate processing apparatus 300, a filter 53 is provided on a downstream side of a bellows pump 27. In conjunction with this, in the substrate processing apparatus 300, a first switching section 25, a second switching section 26, a first branch pipe 38, a second branch pipe 41, a second processing liquid supply section 47, a third processing liquid supply section 48, and a discharge section 45 are also provided on the downstream side of the bellows pump 27.

In the substrate processing apparatus 300, the filter 53 has a pore diameter similar to that of the main filter 33 in the substrate processing apparatus 100 or the like. Further, the substrate processing apparatus 300 includes no main filter 33. That is, the filter 53 functions as a main filter in the substrate processing apparatus 300.

Such a substrate processing apparatus 300 also makes it possible to prevent occurrence of a problem by using a second processing liquid to remove clogging of the filter 53 and then filling the filter 53 and its vicinity with a third processing liquid, as in the case of the process described in Embodiment 1. Note that the substrate processing apparatus 300 may include a third processing liquid supply section 48A instead of the third processing liquid supply section 48 as in the case of the substrate processing apparatus 200.

In each of the above embodiments, the CPU 731 and the memory 732 are shown as components of the controller 73. However, the substrate processing apparatus 300 may include, in addition to a controller 73, a memory (not illustrated) that stores information necessary for control by the controller 73. Alternatively, the substrate processing apparatus 300 may be configured to be capable of communicating with a memory that is external to the substrate processing apparatus 300 and that stores information necessary for control by the controller 73.

### Embodiment 4

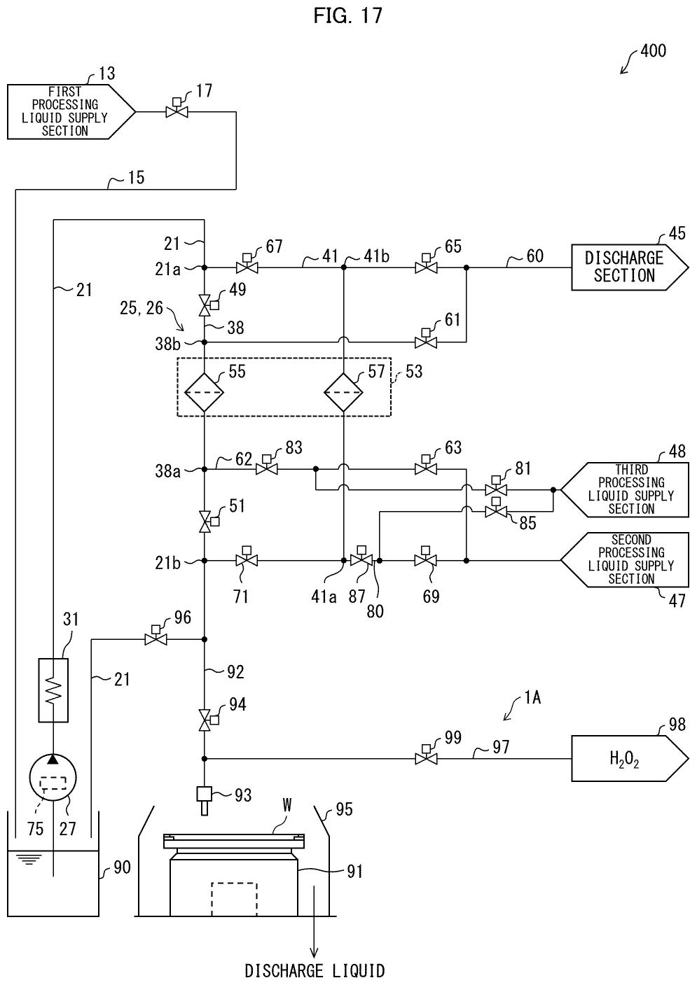

FIG. 17 is an overall view schematically illustrating a configuration of a substrate processing apparatus 400 in accordance with Embodiment 4. The substrate processing apparatus 400 differs from the substrate processing apparatus 300 in that the substrate processing apparatus 400 includes a substrate process tank 1A instead of the substrate process tank 1 and includes a tank 90 which stores a first processing liquid.

The substrate processing apparatus 400 includes the tank 90, which stores the first processing liquid, at a position in a circulation pipe 21 at which position the substrate process tank 1 is provided in the substrate processing apparatus 300. Further, the substrate processing apparatus 400 is provided with a control valve 96 downstream of a first circulation valve 51, instead of the control valve 23 and the control valve 29 that are provided to the circulation pipe 21 in the substrate processing apparatus 300.

The first processing liquid is supplied from a first processing liquid supply section 13 to the tank 90. The first processing liquid stored in the tank 90 is fed under pressure by a bellows pump 27 and circulates via the circulation pipe 21 and the tank 90. Note that the first processing liquid is sulfuric acid in Embodiment 4.

A controller 73 controlling the control valve 96 and a control valve 94 (described later) controls the substrate processing apparatus 400 so as to change processing into a state in which the first processing liquid circulates in the circulation pipe 21 and a state in which a liquid containing the first processing liquid is discharged from nozzle 93 (described later).

The circulation pipe 21 branches to an SPM supply pipe 92, which is a part of the substrate process tank 1A, between the first circulation valve 51 and the control valve 96. Thus, sulfuric acid is supplied to the SPM supply pipe 92 via the circulation pipe 21. More specifically, both ends of the circulation pipe 21 are connected to the SPM supply pipe 92. In other words, both ends of the circulation pipe 21 are connected to the substrate process tank 1A.

To the SPM supply pipe 92, an H₂O₂ supply pipe 97 is connected. The H₂O₂ supply pipe 97 is provided with a control valve 99, and a hydrogen peroxide solution (H₂O₂) is supplied from an H₂O₂ supply section 98 to the SPM supply pipe 92 via the H₂O₂ supply pipe 97.

According to the present configuration, in a case where the control valve 96 is closed, the first circulation valve 51 is opened, and the control valve 99 is opened, sulfuric acid and hydrogen peroxide are mixed in the SPM supply pipe 92 to generate an SPM, and the SPM is discharged, from the nozzle 93 (described later), as the liquid containing the first processing liquid. The SPM is a processing liquid generated by a chemical reaction between sulfuric acid and a hydrogen peroxide solution. However, in the present embodiment, the SPM is defined as the liquid containing the first processing liquid.

The substrate process tank 1A is a so-called single wafer processing section that processes substrates W one by one. The substrate process tank 1A includes not only the foregoing SPM supply pipe 92 but also a spin chuck 91, the nozzle 93, the control valve 94, and a cup 95.

The spin chuck 91 is rotated while a substrate W is held substantially horizontally. The SPM supply pipe 92 is a pipe conduit one end of which is connected to the circulation pipe 21, the other end of which is connected to the nozzle 93, and which is for supplying, to the nozzle 93, the liquid containing the first processing liquid. The nozzle 93 supplies, to a surface of the substrate W held by the spin chuck 91, the liquid containing the first processing liquid. The nozzle 93 is connected to the first processing liquid supply section 13. The control valve 94 is provided to the SPM supply pipe 92 and controls discharge of the liquid from the nozzle 93, the liquid containing the first processing liquid. The cup 95 prevents scattering of the liquid that has been supplied from the nozzle 93 and has scattered from the substrate W, the liquid containing the first processing liquid. The cup 95 is connected to a liquid discharge section (not illustrated) and discharges the liquid containing the first processing liquid with use of which the substrate W has been processed.

### (Operation)

An operation of the substrate processing apparatus 400 will be described with reference to FIG. 3. The following description will discuss only a part different from the operation of the substrate processing apparatus 100.

In the substrate processing apparatus 400, the controller 73 does not carry out a first processing liquid storage step (S2) and starts a circulation processing step (S3) after a filter selection step (S1). In the circulation processing step (S3), the controller 73 controls the control valve 96 and the control valve 94 instead of the control valve 23 and the control valve 29 that are controlled in the substrate processing apparatus 100. The controller 73 opens the control valve 96 and the first circulation valves 49 and 51, and closes the control valve 94. Thus, circulation of the first processing liquid is started via the circulation pipe 21.

Next, in a substrate processing step (S4), the controller 73 of the substrate processing apparatus 400 controls the control valve 96, the control valve 94, and the control valve 99 instead of the lifter 11 that is controlled in the substrate processing apparatus 100. The controller 73 closes the control valve 96 and opens the control valve 94 and control valve 99. Thus, the SPM is generated in the SPM supply pipe 92 and discharged to the substrate W through the nozzle 93. Upon completion of processing of the substrate W, the controller 73 carries out control so as to open the control valve 96 and close the control valve 94 and the control valve 99. Thus, discharge of the SPM to the substrate W is stopped.

In the substrate processing apparatus 400, the controller 73 carries out a first processing liquid temperature determination step (S62) after a first processing liquid flow step (S61). In this case, instead of determining the temperature of the first processing liquid in the inner tank 3 in the substrate processing apparatus 100, the controller 73 uses a temperature sensor (not illustrated) to determine whether the temperature of the first processing liquid in the circulation pipe 21 has been stabilized.

The substrate processing apparatus 400 including such a substrate process tank 1A also makes it possible to appropriately and safely clean a filter 53 while preventing damage to a component constituting the substrate processing apparatus 400. In the substrate processing apparatus 400, at least a part of a second processing liquid present inside the filter 53 is replaced with a third processing liquid. This makes it possible to prevent bumping of the first processing liquid in the circulation pipe 21 and prevent damage to the circulation pipe 21 and unintended discharge of a processing liquid from the nozzle 93.

### Embodiment 5

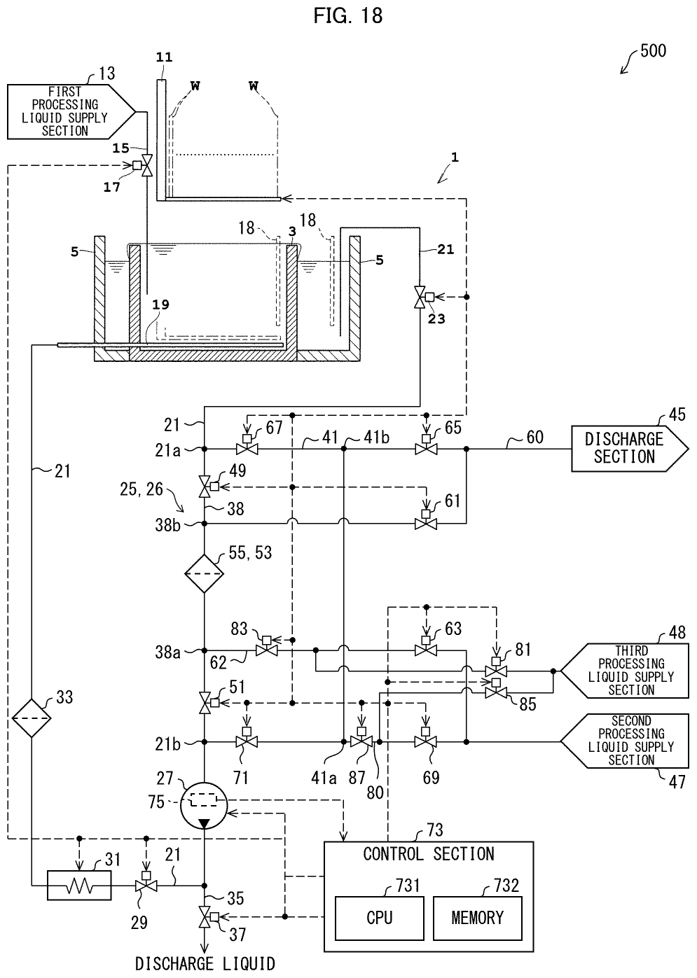

FIG. 18 is an overall view schematically illustrating a configuration of a substrate processing apparatus 500 in accordance with Embodiment 5. The substrate processing apparatus 500 differs from the substrate processing apparatus 100 in that the substrate processing apparatus 500 includes only a first filter 55 as a filter 53 and includes no second filter 57.

Also in the substrate processing apparatus 500, a controller 73 may carry out a first cleaning process. That is, during a period in which a first switching section 25 is controlled so as to allow a first processing liquid to flow into a second branch pipe 41 in a forward direction, the controller 73 controls a second switching section 26 so as to (i) allow a second processing liquid to flow into a first branch pipe 38 in a backward direction and (ii) cause a liquid containing at least the first processing liquid to be discharged from a discharge section 45. Thereafter, the controller 73 further controls the second switching section 26 so as to (iii) allow a third processing liquid to flow into the first branch pipe 38 in the backward direction and (iv) cause a liquid containing at least the second processing liquid to be discharged from the discharge section 45. Further, after the first cleaning process, the controller 73 allows the first processing liquid to flow into the first branch pipe 38 in the forward direction, and allows the second processing liquid and the third processing liquid to flow into the second branch pipe 41 in the backward direction, or stops supply of the second processing liquid and the third processing liquid.

Also in the substrate processing apparatus 500, during a period in which the first switching section 25 is controlled so as to allow the first processing liquid to flow into the first branch pipe 38 in the forward direction, the controller 73 may control the second switching section 26 so as to allow the second processing liquid and the third processing liquid to flow into the second branch pipe 41 in the backward direction.

### REFERENCE SIGNS LIST

1, 1A Substrate process tank (substrate processing section)
3 Inner tank
5 Outer tank
21 Circulation pipe
21a First branch point
21b Second branch point
25 First switching section
26 Second switching section
31 Heater
33 Main filter
38 First branch pipe
38a Third branch point
38b Fifth branch point
41 Second branch pipe
41a Fourth branch point
41b Sixth branch point
45 Discharge section
47 Second processing liquid supply section
48, 48A Third processing liquid supply section
49, 51 First circulation valve
53 Filter
55 First filter
57 Second filter
60 Discharge pipe
61 First discharge valve
63 First-second supply valve
65 Second discharge valve
67, 71 Second circulation valve
69 Second-second supply valve
73 Controller (control section)
81 First-third supply valve
85 Second-third supply valve
100, 200, 300, 400, 500 Substrate processing apparatus

1. A substrate processing apparatus comprising:
a substrate process tank that uses a liquid containing a first processing liquid to process a substrate;
a circulation pipe that has both ends connected to the substrate process tank and that includes a part branching into two pipes, which are a first branch pipe and a second branch pipe;
a filter that filters the first processing liquid;
a second processing liquid supply section that supplies a second processing liquid containing a component different from a component of the first processing liquid;
a third processing liquid supply section that supplies a third processing liquid containing a component different from the component of the second processing liquid;
a discharge section that discharges a liquid containing at least the first processing liquid or the second processing liquid;
a controller;
a first switching section that switches whether to allow the first processing liquid to flow into the first branch pipe or the second branch pipe; and
a second switching section that switches whether to allow the second processing liquid to flow into the first branch pipe or the second branch pipe and whether to allow the third processing liquid to flow into the first branch pipe or the second branch pipe,
the filter being provided to at least the first branch pipe, and
the controller (1) carrying out a first cleaning process in which, during a period in which the first switching section is controlled so as to allow the first processing liquid to flow into the second branch pipe in a forward direction, the second switching section is controlled so as to (i) allow the second processing liquid to flow into the first branch pipe in a backward direction and (ii) discharge, from the discharge section, the liquid containing at least the first processing liquid, and then the second switching section is further controlled so as to (iii) allow the third processing liquid to flow into the first branch pipe in the backward direction and (iv) discharge, from the discharge section, the liquid containing at least the second processing liquid, and (2) after the first cleaning process, allowing the first processing liquid to flow into the first branch pipe in the forward direction, and allowing the second processing liquid and the third processing liquid to flow into the second branch pipe in the backward direction, or stopping supply of the second processing liquid and the third processing liquid.

2. The substrate processing apparatus as set forth in claim 1, wherein
the circulation pipe has first and second branch points at which the circulation pipe branches into the first branch pipe and the second branch pipe,
the first switching section includes
a pair of first circulation valves provided to the first branch pipe, and
a pair of second circulation valves provided to the second branch pipe,
the filter is provided between the pair of first circulation valves, and
the controller allows the first processing liquid to flow into the first branch pipe by opening the pair of first circulation valves and closing the pair of second circulation valves, and allows the first processing liquid to flow into the second branch pipe by closing the pair of first circulation valves and opening the pair of second circulation valves.

3. The substrate processing apparatus as set forth in claim 2, further comprising
a first supply pipe which connects the second processing liquid supply section and the third processing liquid supply section with the first branch pipe,
a second supply pipe which connects the second processing liquid supply section and the third processing liquid supply section with the second branch pipe, and
a discharge pipe which connects the first branch pipe and the second branch pipe with the discharge section,
the first branch pipe having a third branch point which is between the filter and one of the pair of first circulation valves on a downstream side in the forward direction and at which the first supply pipe branches off from the first branch pipe,
the second branch pipe having a fourth branch point which is between the filter and one of the pair of second circulation valves on the downstream side in the forward direction and at which the second supply pipe branches off from the second branch pipe,
the first branch pipe having a fifth branch point which is between the filter and the other of the pair of first circulation valves on an upstream side in the forward direction and at which the discharge pipe branches off from the first branch pipe,
the second branch pipe having a sixth branch point which is between the filter and the other of the pair of second circulation valves on the upstream side in the forward direction and at which the discharge pipe branches off from the second branch pipe,
the second switching section including
a first supply valve which is located on the first supply pipe side of the third branch point,
a second supply valve which is located on the second supply pipe side of the fourth branch point,
a first discharge valve which is located on the discharge pipe side of the fifth branch point, and
a second discharge valve which is located on the discharge pipe side of the sixth branch point,
while allowing the first processing liquid to flow into the first branch pipe by opening the pair of first circulation valves and closing the pair of second circulation valves, the controller closing the first supply valve, opening the second supply valve, closing the first discharge valve, and opening the second discharge valve, and
while allowing the first processing liquid to flow into the second branch pipe by closing the pair of first circulation valves and opening the pair of second circulation valves, the controller opening the first supply valve, closing the second supply valve, opening the first discharge valve, and closing the second discharge valve.

4. The substrate processing apparatus as set forth in claim 1, wherein
the filter is further provided to the second branch pipe, and
the controller (1) carries out a second cleaning process in which, during a period in which the first switching section is controlled so as to allow the first processing liquid to flow into the first branch pipe in the forward direction, the second switching section is controlled so as to (i) allow the second processing liquid to flow into the second branch pipe in the backward direction and (ii) discharge, from the discharge section, the liquid containing at least the first processing liquid, and then the second switching section is further controlled so as to (iii) allow the third processing liquid to flow into the second branch pipe in the backward direction and (iv) discharge, from the discharge section, the liquid containing at least the second processing liquid, and (2) after the second cleaning process, allows the first processing liquid to flow into the second branch pipe in the forward direction, and allows the second processing liquid and the third processing liquid to flow into the first branch pipe in the backward direction, or stops supply of the second processing liquid and the third processing liquid.

5. The substrate processing apparatus as set forth in claim 1, wherein the first processing liquid is a processing liquid containing sulfuric acid, and the second processing liquid is pure water.

6. The substrate processing apparatus as set forth in claim 1, wherein the first processing liquid is phosphoric acid, and the second processing liquid is a processing liquid containing hydrofluoric acid.

7. The substrate processing apparatus as set forth in claim 1, wherein
the circulation pipe includes a heater which heats the first processing liquid to a prescribed temperature, and
the second processing liquid supply section supplies the second processing liquid at normal temperature.

8. The substrate processing apparatus as set forth in claim 1, wherein
the third processing liquid supply section supplies the third processing liquid to the filter by branching off from the circulation pipe, and
the third processing liquid is the first processing liquid which circulates in the circulation pipe.

9. The substrate processing apparatus as set forth in claim 8, wherein
the substrate process tank includes an inner tank which stores the first processing liquid that has been supplied from the circulation pipe and an outer tank which stores the first processing liquid that has overflowed from the inner tank,
the circulation pipe has one end which is connected to the outer tank and the other end which is connected to the inner tank, and
the third processing liquid supply section supplies the third processing liquid to the filter at a flow rate lower than a flow rate at which the first processing liquid overflows from the inner tank to the outer tank.

10. The substrate processing apparatus as set forth in claim 4, wherein
in the second cleaning process, the controller allows the third processing liquid to flow into the second branch pipe in the backward direction immediately before an end of a period in which the first switching section is controlled so as to circulate the first processing liquid in the first branch pipe, and
in the first cleaning process, the controller allows the third processing liquid to flow into the first branch pipe in the backward direction immediately before an end of a period in which the first switching section is controlled so as to circulate the first processing liquid in the second branch pipe.

11. The substrate processing apparatus as set forth in claim 3, wherein
the second switching section further includes
a first-second supply valve which switches whether the second processing liquid flows from the second processing liquid supply section into the first branch pipe,
a first-third supply valve which switches whether the third processing liquid flows from the third processing liquid supply section into the first branch pipe,
a second-second supply valve which switches whether the second processing liquid flows from the second processing liquid supply section into the second branch pipe, and
a second-third supply valve which switches whether the third processing liquid flows from the third processing liquid supply section into the second branch pipe, and
the controller carries out control
such that, in a state in which the pair of first circulation valves is opened, the pair of second circulation valves is closed, and the second supply valve is opened, the second-second supply valve is opened for a prescribed period, and then the second-third supply valve is opened for a prescribed period, and
such that, in a state in which the pair of second circulation valves is opened, the pair of first circulation valves is closed, and the first supply valve is opened, the first-second supply valve is opened for a prescribed period, and then the first-third supply valve is opened for a prescribed period.

12. The substrate processing apparatus as set forth in claim 1, further comprising a main filter which is provided on the downstream side of the filter in the circulation pipe,
the filter being a prefilter, and the main filter having a smaller pore diameter than the prefilter.

13. The substrate processing apparatus as set forth in claim 1, wherein a member which is included in the substrate process tank and through which the first processing liquid passes is made of a material containing quartz.

14. A substrate processing method carried out in a substrate processing apparatus including:
a substrate process tank that uses a liquid containing a first processing liquid to process a substrate;
a circulation pipe that has both ends connected to the substrate process tank and that includes a part branching into two pipes, which are a first branch pipe and a second branch pipe;
a filter that filters the first processing liquid;
a second processing liquid supply section that supplies a second processing liquid containing a component different from a component of the first processing liquid;
a third processing liquid supply section that supplies a third processing liquid containing a component different from the component of the second processing liquid;
a discharge section that discharges a liquid containing at least the first processing liquid or the second processing liquid;
a first switching section that switches whether to allow the first processing liquid to flow into the first branch pipe or the second branch pipe; and
a second switching section that switches whether to allow the second processing liquid to flow into the first branch pipe or the second branch pipe and whether to allow the third processing liquid to flow into the first branch pipe or the second branch pipe, wherein
the filter is provided to at least the first branch pipe,
(1) a first cleaning process is carried out in which, during a period in which the first switching section is controlled so as to allow the first processing liquid to flow into the second branch pipe in a forward direction, the second switching section is controlled so as to (i) allow the second processing liquid to flow into the first branch pipe in a backward direction and (ii) discharge, from the discharge section, the liquid containing at least the first processing liquid, and then the second switching section is further controlled so as to (iii) allow the third processing liquid to flow into the first branch pipe in the backward direction and (iv) discharge, from the discharge section, the liquid containing at least the second processing liquid, and
(2) after the first cleaning process, the first processing liquid is allowed to flow into the first branch pipe in the forward direction, and the second processing liquid and the third processing liquid are allowed to flow into the second branch pipe in the backward direction, or supply of the second processing liquid and the third processing liquid is stopped.

15. A substrate processing method comprising:
a substrate processing step of using a liquid containing a first processing liquid to process a substrate in a substrate process tank;
a circulation processing step of using a filter provided to at least a first branch pipe of a circulation pipe to filter the first processing liquid which flows in the circulation pipe in a forward direction, the circulation pipe having both ends connected to the substrate process tank, and including a part branching into two pipes, which are the first branch pipe and a second branch pipe; and
a processing resumption step of (I) carrying out a first cleaning process in which, during a period in which a first switching section that switches whether to allow the first processing liquid to flow into the first branch pipe or the second branch pipe is controlled so as to allow the first processing liquid to flow into the second branch pipe in a forward direction, a second switching section that switches whether to allow a second processing liquid containing a component different from a component of the first processing liquid to flow into the first branch pipe or the second branch pipe and whether to allow a third processing liquid containing a component different from the component of the second processing liquid to flow into the first branch pipe or the second branch pipe is controlled so as to (i) allow the second processing liquid to flow into the first branch pipe in a backward direction and (ii) discharge, from a discharge section that discharges a liquid containing at least the first processing liquid or the second processing liquid, the liquid containing at least the first processing liquid, and then the second switching section is further controlled so as to (iii) allow the third processing liquid to flow into the first branch pipe in the backward direction and (iv) discharge, from the discharge section, the liquid containing at least the second processing liquid, and (II) after the first cleaning process, resuming circulation of the first processing liquid in the first branch pipe.
